(19) United States
(12) Patent Application Publication
(10) Pub. No.: US 2007/0279657 A1
(43) Pub. Date: Dec. 6, 2007

(54) Color converting device, method, and program-storing recording medium

(75) Inventors: Yasunari Kishimoto, Kanagawa (JP); Noriko Hasegawa, Kanagawa (JP); Tomoko Taguchi, Kanagawa (JP); Kiyoshi Une, Saitama (JP)

Correspondence Address: OLIFF & BERRIDGE, PLC, P.O. BOX 19928, ALEXANDRIA, VA, 22320, US

(73) Assignee: FUJI XEROX CO., LTD., TOKYO (JP)

(21) Appl. No.: 11/641,681

(22) Filed: Dec. 20, 2006

(30) Foreign Application Priority Data
Jun. 6, 2006 (JP) 2006-157162

(51) Int. Cl. G03F 3/08

(52) U.S. Cl. 358/1.9; 358/518

(57) ABSTRACT

There is provided a color converting device, wherein base data regulates a plurality of color charts regarding a first color value on a first color space and a second color value on a second color space that represent colors of a specified color chart and a color prediction model that estimates and calculates the relation between the first color value and the second color value based on the base data are inputted or designated, and the inputted or designated base data and color prediction model are used and color conversion conditions for converting the first color value to the second color value are generated, the device performing color conversion of inputted image data based on the generated color conversion conditions and provided with a determining unit that determines with calculation processing whether the inputted or designated base data is base data that can generate suitable color conversion conditions when the base data is combined with the inputted or designated color prediction model.

### BACKGROUND

1. Technical Field

The present invention relates to a color converting device, method, and program-storing medium. More specifically, it relates to a color converting device that generates color conversion conditions using inputted or designated base data and color prediction model and performs color conversion of image data; to a color conversion method applicable to the color converting device; and to a recording medium in which a color conversion program for making a computer function as a color converting device is stored.

2. Related Art

The color reproducing regions and color reproducing characteristics of output devices such as color printers, displays and scanners that are connected to computers all differ from each other. For this reason, the operating system (OS) running on the computer has a profile. When receiving and sending colors data between each device, the OS follows the profile created/submitted with each device from the manufacturer of each device in accordance with the color reproducing characteristics of each device. (That is, the OS follows color conversion conditions for converting a color value of a color space to a corresponding color value. The color conversion conditions primarily in use are conditions that perform color conversion between device-dependent color space that depend on a specified device and device-independent color space that do not depend on a specified device.) The system is equipped with a color management system that performs color conversion, by which differences in color reproducing qualities in each device are corrected, and it performs matching of the reproduced colors at each device. (Apple Computer Co.'s ColorSync and Microsoft's ICM are examples of color management system.)

### SUMMARY

According to an aspect of the present invention, there is provided a color converting device, wherein base data regulates a plurality of color charts regarding a first color value on a first color space and a second color value on a second color space that represent colors of a specified color chart and a color prediction model that estimates and calculates the relation between the first color value and the second color value based on the base data are inputted or designated, and the inputted or designated base data and color prediction model are used and color conversion conditions for converting the first color value to the second color value are generated, the device performing color conversion of inputted image data based on the generated color conversion conditions and provided with a determining unit that determines with calculation processing whether the inputted or designated base data is base data that can generate suitable color conversion conditions when the base data is combined with the inputted or designated color prediction model.

### BRIEF DESCRIPTION OF THE DRAWINGS

Exemplary embodiments of the present invention will be described in detail based on the following figures, wherein:

FIG. 1 is a block diagram showing the overall structure of a computer system according to the present embodiments;

FIG. 2 is an outline diagram showing the overall flow of color management processing with the color management system;

FIG. 3 is an outline diagram showing the flow of color conversion in the color management system;

FIG. 4 is a flowchart showing the content of color conversion processing executed with the color management system;

FIG. 5 is a flowchart showing the content of base data determination processing of the first embodiment;

FIG. 6 is a line drawing for explaining precision determination of base data based on a color difference;

FIG. 7 is a flowchart showing the content of base data determination processing of the second embodiment;

FIG. 8A is a flowchart showing the content of base data determination processing of the third embodiment;

FIG. 8B is a flowchart showing the content of base data determination processing of the third embodiment;

FIG. 9A is a flowchart showing the content of base data determination processing of the fourth embodiment;

FIG. 9B is a flowchart showing the content of base data determination processing of the fourth embodiment;

FIG. 10A is a flowchart showing the content of base data determination processing of the fifth embodiment;

FIG. 10B is a flowchart showing the content of base data determination processing of the fifth embodiment;

FIG. 11A is a flowchart showing the content of base data determination processing of the sixth embodiment;

FIG. 11B is a flowchart showing the content of base data determination processing of the sixth embodiment;

FIG. 12A is a flowchart showing the content of base data determination processing of the seventh embodiment; and

FIG. 12B is a flowchart showing the content of base data determination processing of the seventh embodiment.

### DETAILED DESCRIPTION

Hereafter, examples of the embodiments of the present invention will be explained in detail while referring to the drawings.

### First Embodiment

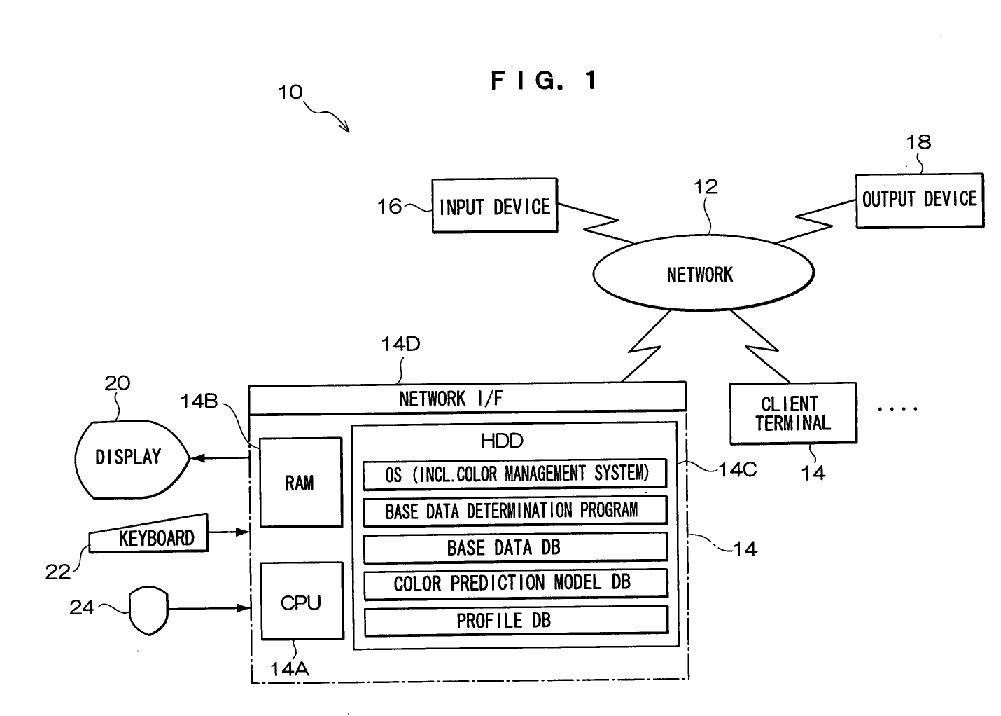

The general structure of a computer system 10 according to the present embodiment is shown in FIG. 1. The computer system 10 is configured such that each of: a LAN or the like; multiple client terminals 14 that are devices such as personal computers (PCs); an input device 16 that inputs images (i.e., data) to the computer system 10; and an output device 18 that makes image data inputted from the computer system 10 viewable as images is connected to a network 12. Note that an example of the input device 16 includes a scanner that scans a manuscript (original) and outputs image data, and for the output device 18, a device can be used such as a printer that prints images representing inputted image data onto paper. Further, the network 12 is also connected to a computer network such as the Internet, but this has been omitted from the drawings.

Each of the individual client terminals 14 connected to the network 12 is provided with a CPU 14A, a memory 14B that is a device such as a RAM, a hard disk drive (HDD) 14C, and a network interface (I/F) 14D. The client terminal 14 is connected to the network 12 via the network I/F 14D. Also, a display 20 that is a type of output device is connected to the client terminal 14, as is a keyboard 22 and a mouse 24 that act as inputting units. Note that the input device 16 and the output device 18 can, like the display 20, can be directly connected to the client terminal 14 as well. For example, another device besides a scanner can be used for the input device 16, such as a digital still camera, which is directly connected to the client terminal 14.

Further, various programs are installed in the HDD 14C of the client terminal 14 in advance, such as operating system (OS) programs, base data determination programs for the CPU 14A that performs base data determination processing, which will be described later, and various application programs (not shown) that use the input and output devices. Also stored therein are each of a profile data base (DB) for storing a profile used in color conversion processing that will be described later, a color prediction model DB for storing a color prediction model, and a base data DB for storing base data. Note that the profile, color prediction model, and base data will be explained later.

A color management program for making the client terminal 14 function as a color management system, which will be described later, is also included in the OS programs. Also, the base data determination processing is processing that corresponds to a determination unit according to the present invention, and the base data determination program corresponds to the color conversion program in the present invention. The client terminal 14 executes the above-mentioned color management program and the base data determination program, whereby the client terminal 14 functions as the color conversion device according to the present invention.

The HDD 14C that stores the above-described profile DB, color prediction model DB, and base data DB corresponds to each of a color prediction model storage unit, a base data storage unit, and a color conversion conditions storage unit in the embodiments of the present invention, respectively. Note that a server computer is provided in the computer system 10, and the above-described profile DB, color prediction model DB, and base data DB can be stored in the server computer HDD or the like so that each are accessible from the individual client terminal 14.

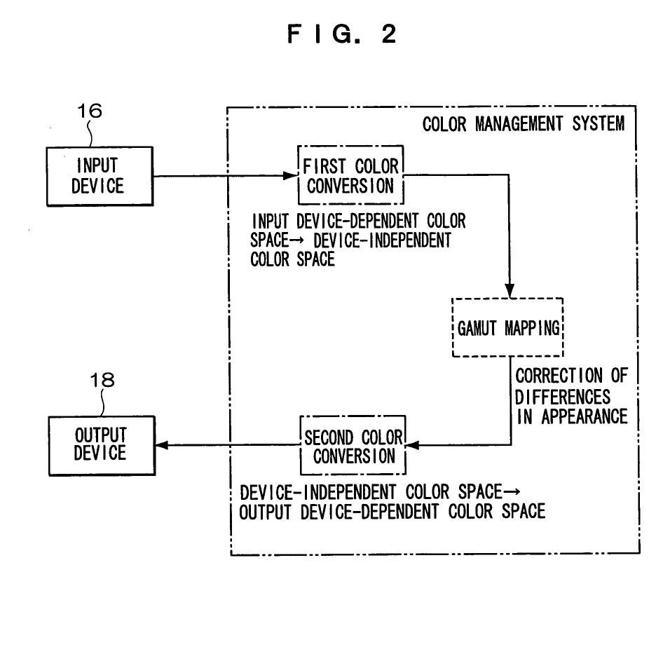

Next, the operation of the first embodiment of the present invention will be explained. The color management system built in the OS running on the client terminal 14 performs the color management processing shown in FIG. 2. That is, image data inputted from the input device 16 to the client terminal 14 is image data that represents the colors of individual pixels of the image data with color values on a color space that depends on the input device 16 (e.g., a RGB color space). The color management system performs a first color conversion processing (see FIG. 2) on the image data inputted from the input device 16 to the client terminal 14 at a certain timing (such as when inputting image data to the client terminal 14 or when outputting image data to the output device 18) and converts the color value on the color space that depends on the input device 16 into a color value on a color space that does not depend on a particular device (e.g., models with visible color such as L*a*b* color space or XYZ color space or CAM02 space).

Further, with the output of image data from the client terminal 14 to the output device 18, it is necessary to output to the output device 18 image data representing the colors of each individual pixel with color values on the color space that depends on the output device 18 (e.g., a CMYK color space or a RGB color space and the like). For this reason, the color management system performs a second color conversion processing (see FIG. 2) that converts the color values on the color space not depending on a particular device into color values on a color space that depends on the output device 18 (e.g., a CMYK color space or a RGB color space). Note that the color management system can be configured so that the above-described color appearance model is applied as the color space not depending on a specific device, and so as to perform color conversion processing on the image data that underwent first color conversion. This color conversion processing corrects the difference between the image appearance in the 26 and the image appearance in the output device 18 (this difference in appearances is caused by factors such as discrepancies in the image observation conditions). (In FIG. 2, the color conversion processing that corrects the difference in appearances is listed and shown as “gamut mapping”.)

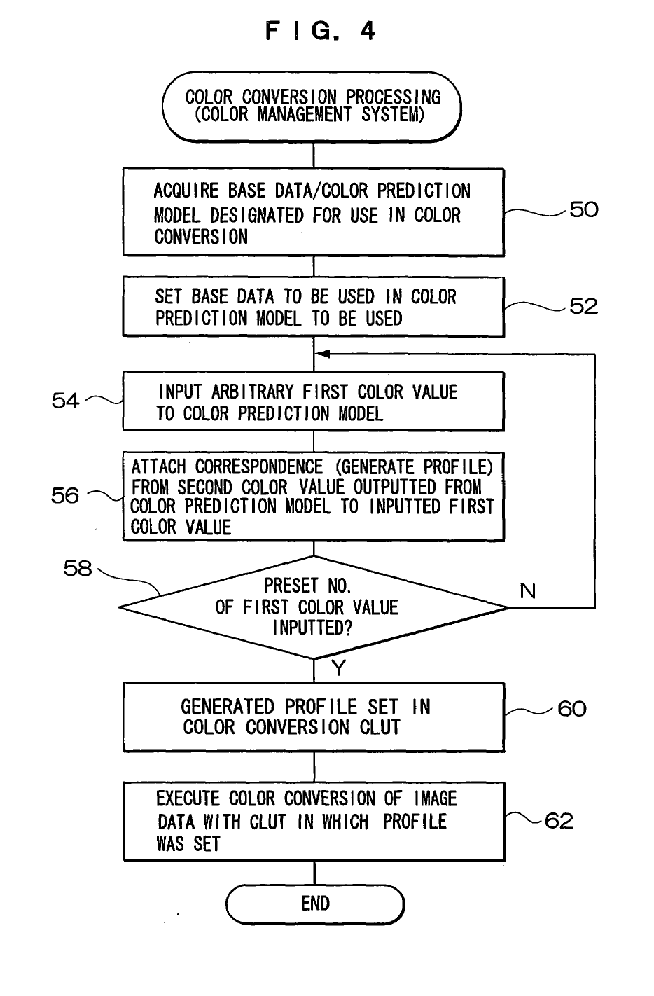

Further, the above-mentioned first color conversion processing and second color conversion processing (hereafter, simply referred to as “color conversion processing”) are performed by the color management system performing the color conversion processing shown in FIG. 4. Hereafter, this color conversion processing will be explained.

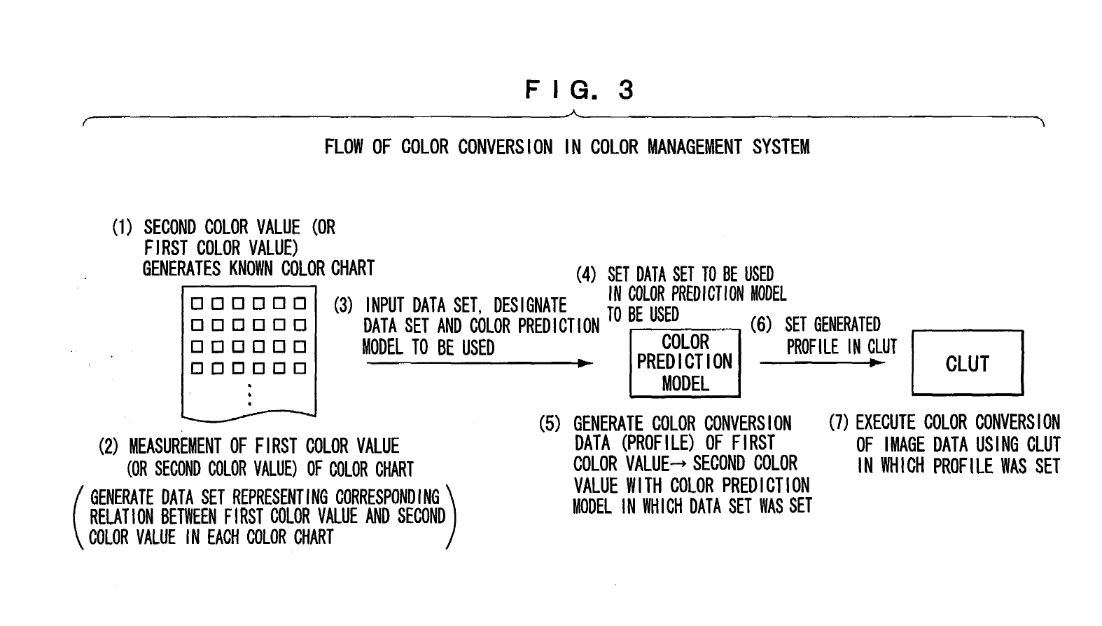

The color conversion processing performed by the color management system sets conversion data (a profile) that converts inputted color values (first color values on a first color space (i.e., input color space)) into outputted color values (second color values on a second color space (i.e., output color space)) to a CLUT. This is made due to sequential inputting of image data of the object to be converted (i.e., image data representing the colors of each pixel with the inputted color values) to the CLUT. Here, for the method of generating a profile, one of the inputted color value and outputted color value generates patches of well-known colors (color chart), as is shown in FIG. 3(1). (For example, when generating a profile for second color conversion processing upon outputting image data to the printer functioning as the output device 18, generation of the color chart is performed by the outputted color value printing a well-known color chart with the printer. When generating a profile for second color conversion processing upon outputting image data to the display 20 functioning as an output device, generation of the color chart is performed by the outputted color value displaying a well-known color chart on the display 20.) A method is known where, with regard to each of the generated color charts, the unknown color values in the inputted color value and outputted color value are each measured with a device such as a calorimeter, whereby data to be attached to each color chart corresponding to each inputted color value and outputted color value is sought and this data is used as the profile.

However, with the above-described generation method, a huge number of color charts are generated and it is necessary to measure the inputted color value or outputted color value for the huge number of color charts, so there has been a problem in that there is a lot of labor involved in generating a profile. For this reason, a method utilizing a color prediction model is also used as another method for generating a profile. A color prediction model is a program that, based on base data representing the corresponding relations between a smaller number of inputted color value and outputted color value, when unknown inputted color value are inputted into the corresponding outputted color value, the program performs estimation calculations for the outputted color value corresponding to the inputted inputted color value with various algorithms and outputs them. In the generation of a profile using a color prediction model, a lesser number of color charts (i.e., color charts where the inputted color value and outputted color value are well-known) are generated than in a case where a direct profile is generated from color charts (see also FIG. 3(1)). With each of the generated color charts, the unknown color values among the inputted color value and outputted color value are measured, whereby base data corresponding to the inputted color value and outputted color value of each color chart is generated (see FIG. 3(2) as well). Note that the base data generated with this process corresponds to the base data in the embodiment of the present invention. Next, this base data is set in the color prediction model (see also FIG. 3(4)) and each inputted color value is inputted in order to the color prediction model. The profile is generated by attaching an association between the outputted color value outputted in order from the color prediction model and the inputted inputted color value (see also FIG. 3(5)). Then, the generated profile is set in the LUT (see FIG. 3(6)), whereby the performance of color conversion with that LUT becomes possible.

When compared to a case where a direct profile is generated from color charts, generating a profile that uses a color prediction model shows that the number of necessary color charts can be greatly reduced so the labor involved in profile generation can also be greatly reduced. The color management system according to the present embodiment employs a generation method using base data and a color prediction model for the profile-generating method. The base data and color prediction model used in generating the profile can be designated by a user.

For this reason, upon the execution of color conversion (first color conversion) on the image data inputted from a specified input device or of color conversion (second color conversion) on the image data outputted to a specified output device, when desiring to use a profile generated using specified base data (e.g., base data created by the user himself) or specified color prediction model, the user performs an operation of creating base data as necessary (see FIG. 3 (1) and (2)). After that, the created base data is inputted/designated (the base data inputted by the user is stored in the base data DB) as the base data used in color conversion (generation of the profile). Operations are performed in advance where the base data used in color conversion (generation of the profile) is designated from within the base data stored in the base data DB, and the color prediction model used in color conversion (generation of the profile) is designated from within the color prediction model stored in the color prediction model DB (see FIG. 3 (3)).

As shown in FIG. 4, with the color conversion processing performed by the color management system, first, in Step 50, the base data and the color prediction model are recognized and these are designated by the user for the base data and color prediction model that will be used in the color conversion (profile generation) to be executed. Processing is performed where the recognized base data is obtained from the base data DB and the recognized color prediction model is obtained from the color prediction model DB. Note that in a case where the base data and the color prediction model to be used are not designated by the user, base data and a color prediction model set as items to be used by default are obtained.

At the next Step 52, the base data to be used that was obtained at Step 50 is set in the color prediction model to be used that was also obtained at Step 50 (see FIG. 3 (4)). At Step 54, an arbitrary first color value (inputted color value) is inputted to the color prediction model in which the base data was set, and at the next Step 56, the second color value outputted from the color prediction model accompanies the inputting of the first color value in Step 54, and correspondence is attached to the first color value inputted to the color prediction model at Step 54 and then stored in the memory 14B. At Step 58, a determination is made regarding whether or not a predetermined number of first color value was inputted into the color prediction model. In the case of a negative determination, the process returns to Step 54 and Steps 54-58 are repeated until the determination at Step 58 is affirmative. During this process, at Step 54, for the first color value inputted into the color prediction model, the color value corresponding to the apexes (grid points) of each cubic region when the first color space is divide up into many cube-shaped regions in a grid pattern are sequentially selected and inputted. Due to this, the profile (color conversion conditions) that attaches each correspondence to the first color value and the second color value in the position of each grid point is generated (stored) in the memory 14B (see FIG. 3 (5)).

When the determination at Step 58 becomes affirmative, the routine moves to Step 60 and the profile generated with the above-described processing is set in a color conversion CLUT (see FIG. 3 (6)). Then at Step 62, the image data of the object to be color converted is sequentially inputted into the CLUT in which the profile was set, whereby the above-described color conversion of image data is performed (see FIG. 3 (7)), and the color conversion processing is completed.

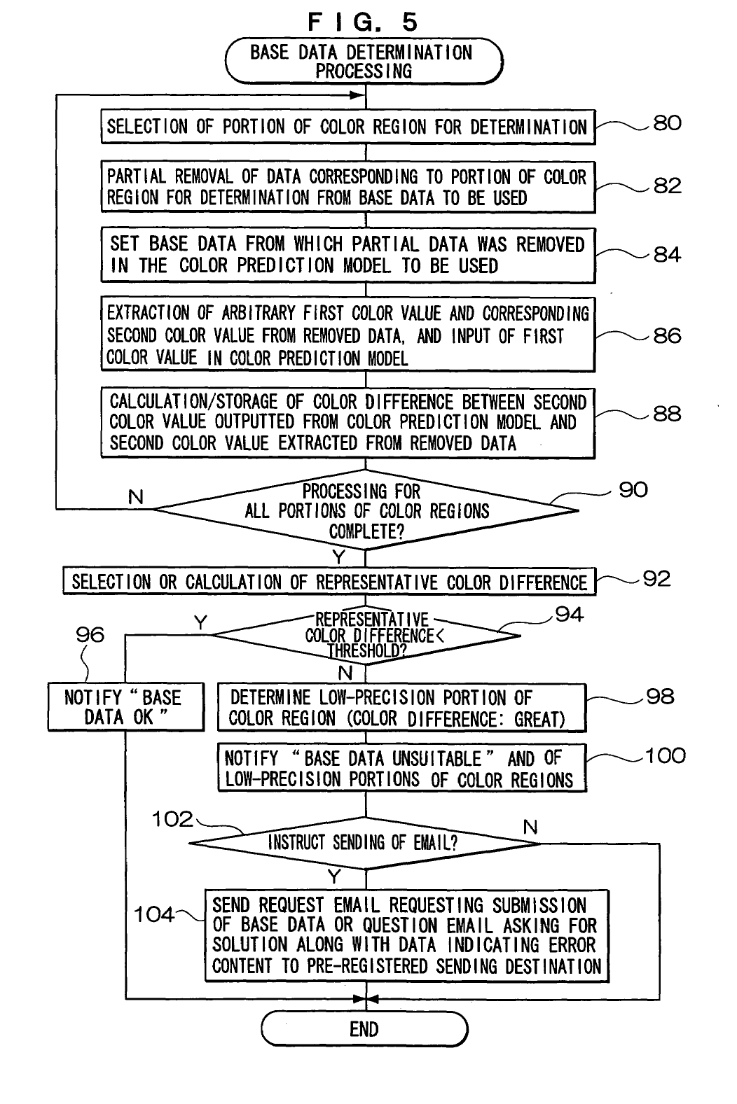

As a note, with the above color conversion processing, arbitrary base data and arbitrary color prediction model can be used in the generation of the profile so, depending on the combination of the base data and color prediction model used in the generation of the profile, there is a possibility that a suitable profile, which can perform suitable color conversion, cannot be obtained. For this reason, a base data determination program is installed in the client terminal 14 according to the present embodiment. The base data determination program is launched by the user and base data determination processing (FIG. 5) is executed at the client terminal 14 in order to confirm the propriety of the base data and color prediction model combination when, for example, the base data and color prediction model combination slated for use in generation of the profile is a combination that has not been used in the past and has no data on actual results. Note that this base data determination processing is not limited to being executed as described above as an instruction from a user. The system can be configured so that the base data determination processing is called up from the color management system when the color management system executes color conversion processing and thus executed each time.

With the base data determination processing, first, in Step 80, the first color space (inputted color space) is divided into multiple portions of color regions and one of those multiple portions of color regions is selected as a portion of a color region upon which determination will be performed. Note that the portions of color regions can also be regions obtained by dividing a second color space (outputted color space). At the next Step 82, the base data (base data of the object of determination in base data determination processing) to be used and designated by the user as the base data used in color conversion (generation of the profile therefor) is recognized. The base data of the recognized object to be used is acquired from the base data DB. A portion of the data (the combination of first and second color values representing each color within the portion color regions that will be determined) corresponding to the portions of color regions to be determined, that were selected at Step 80 from the base data of the object of use that was acquired, is excluded. Note that the amount of data to be excluded data can be a data amount of a first predetermined ratio relative to the overall amount of data corresponding to the portions of color regions that will be determined included in the base data to be used. Also, it can be a data amount of a second predetermined ratio relative to the overall amount of data of the base data to be used.

At Step 84, the color prediction model designated by the user to be used is recognized as the color prediction model used in color conversion (generation of the profile therefor). After acquiring the color prediction model of the recognized object to be used from the color prediction model DB, the base data where a portion of the data corresponding to the portions of color regions for determination was excluded at Step 82, is set in the color prediction model of the object of use. Note that the color prediction model in which base data, where a portion of the data was excluded, is set corresponds to color conversion conditions used in evaluation in the embodiment of the present invention. Also, at Step 86, an arbitrary first color value and a corresponding second color value is extracted from a portion of the data corresponding to portions of color regions to be determined excluded from base data at Step 82, and the extracted first color value is inputted to the above-described color prediction model. Then at Step 88, the second color value (the second color value on the original base data) extracted from the data excluded at Step 86, and the inputting of the first color value in Step 86 is accompanied by calculation of a difference in color between the first color value and the second color value outputted from the color prediction model (the second color value outputted from the evaluation color prediction model). The calculated color difference is stored in the memory 14B. Note that with regard to a single portion of color region that will undergo determination, the system can be configured so that Steps 86 and 88 are performed multiple times and the average value of color differences, or the central value, the greatest value and the like obtained with processing each time can be stored as the color difference in the portions of color regions.

At the next Step 90, it is determined whether the above-described processing on all of the portions of color regions was performed. When the determination is negative, the process returns to Step 80 and Steps 80-90 are repeated until the determination at Step 90 is affirmative. Due to this, with regard to individual portions of color regions, the process becomes such that the color differences between the second color value on the original base data and the second color value outputted from the color prediction model for evaluation are each calculated and stored. When the determination at Step 90 is affirmative, the process moves to Step 92 and a color difference (representative color difference) representing the base data to be used is calculated based on each calculation and storage of the color difference regarding each individual portions of color regions. Any one of, for example, the average absolute value of the color difference of each portions of color regions, or the central value or the standard deviation of the color difference (or the dispersion) can be used for the representative color difference. Further, this can be set so that the greatest value selected from within each color difference of each portions of color regions can be used for the representative color difference.

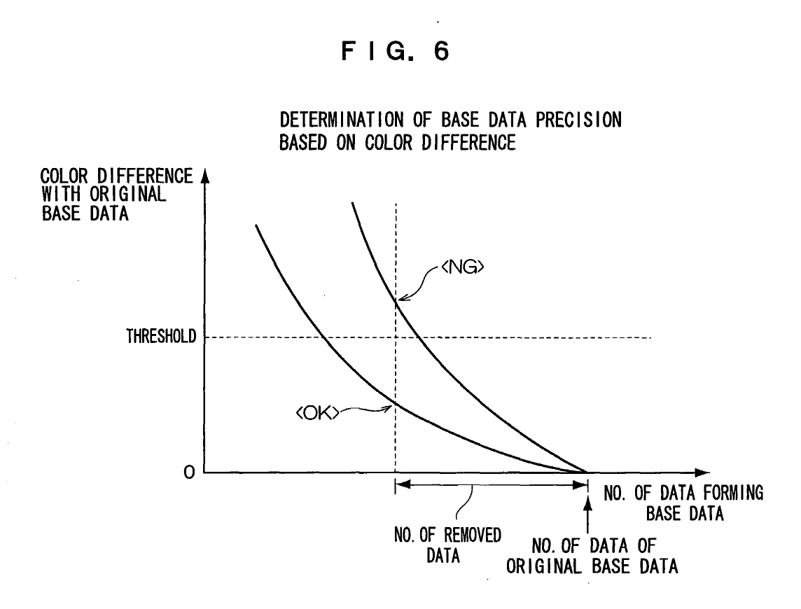

At the next Step 94, it is determined whether the representative color difference calculated or selected at Step 92 is below a threshold. When the base data where a portion of the data has been excluded is set in the evaluation color prediction model as described above, the precision of the color conversion deteriorates when compared to a case where the original base data (base data where a portion of the data has not been excluded) is set in the color prediction model, and what accompanies this is that the above-described color difference is generated and the amount of data that is excluded increases. Accordingly, the amount of deterioration in color conversion precision increases and the above-described color difference becomes larger. However, in the case where the number of data corresponding to each portions of color regions included in the original base data is sufficient relative to the number of data necessary for the color prediction model for each portions of color regions, “OK” is displayed as in the example in FIG. 6, and the precision of the color conversion does not deteriorate too much when compared with the amount of excluded data, and the color difference also becomes a relatively small value. In contrast, when the number of data of specified portion of color regions included in the original base data is insufficient relative to the number of data necessary for the color prediction model for specified portion of color regions, “NG” is displayed as in the example in FIG. 6, and the precision of the color conversion greatly deteriorates when compared with the amount of excluded data, and the color difference also becomes a relatively large value.

Accordingly, even when any one of the average value, middle value or greatest value of the absolute value of the color difference or the standard deviation (or dispersion) of the color difference is used for the representative color difference, the value of the representative color difference becomes smaller when the data corresponding to each portion of color regions is sufficiently included in the original base data. The value of the representative color difference becomes larger when the portion of color regions where the data corresponding to the original base data exists, or in the case of base data where the data overall is insufficient. With the base data determination processing according to the present embodiment, a determination is made at Step 94 with regard to the small/large relation between the representative color difference and the threshold based on the above. Note that the above-described Steps 80-94 correspond to the determination unit in the embodiment of the present invention.

When the determination at Step 94 is affirmative (when the base data displays “OK” in FIG. 6 and the qualities are shown), the routine moves to Step 96. The fact that the combination of the base data designated for use in the color conversion (generation of profile therefor) and the color prediction model is a suitable combination where sufficient accuracy of color conversion conditions (profile) can be obtained is notified to the user by displaying a message or the like on the display 20, and then the base data determination processing is finished. In this case, the user can recognize that the base data designated for use and the color prediction model are a suitable combination, and the user can make the color management system perform color conversion processing with the above-described combination as is.

If, however, the determination at Step 94 is negative (when the characteristics of the base data is as displayed “NG” in FIG. 6), the routine moves to Step 98. As a low-precision portion of color regions where the precision of the color conversion is estimated to be low, the color difference calculated at Step 88 extracts a relatively large portion of color regions. Note that the number of low-precision portion of color regions extracted can be any one of one, or a predetermined multiple number or an indefinite number. When extracting only one low-precision portion of color regions, the representative color difference extracts the largest portion of color regions. When extracting a predetermined number of multiple low-precision portion of color regions, the predetermined number of portion of color regions can be selected and extracted in the descending order of the representative color difference. When extracting an indefinite number of low-precision portion of color regions, all of the portion of color regions, e.g., all of the portion of color regions of the representative color difference at a threshold or above can be extracted.

Note that in the portion of color region, there are regions where the extent of involvement to the precision of color conversion is great due to extensive use at the time of color conversion, and there are regions where the extent of involvement to the precision of color conversion is slight because of almost no use at the time of color conversion. The system can be configured so that the extracted result of the low-precision portion of color region at Step 98 is that, when the portion of color region is only a region where the extent of involvement to the precision of color conversion is slight, the base data and the color prediction model designated for use are determined to be a suitable combination, and the routine moves to Step 96. Note that this Step 98 corresponds to a low precision region detector in the embodiment of the present invention with the Steps 80-92. More specifically, this step corresponds to the low precision region detector “that detects portion of color region as the low-precision portion of color region where the color difference is greater than other portion of color region”.

At the next Step 100, the fact that the combination of the base data and the color prediction model designated for use in the color conversion (generation of profile therefor) is an unsuitable combination where sufficient color conversion conditions of precision (profile) cannot be obtained is notified to the user by the displaying of a message and the like on the display 20, while also notifying of the low-precision portion of color region extracted at Step 98. Note that Step 100 acts as the informing unit in the embodiment of the present invention.

Further, when the base data determination processing according to the present embodiment has determined that the combination of the base data and the color prediction model designated for use is an unsuitable combination, the system is also provided with a function that notifies a sending destination registered in advance by the user with an email having standard text or text registered by the user in advance. At the next Step 102, it is determined whether sending of the above-described email has been instructed by the user. Note that the system can be made so as to ask the user whether to send the email each time a determination has been made that the combination of the base data and color prediction model is an unsuitable combination. When the determination at Step 102 is negative, none of the processes are performed and the base data determination processing finishes.

Users that do not use the above-described email sending function tend to have an abundance of knowledge relating to base data and color prediction model as well as know-how regarding solutions for responding to cases where the combination of the base data and color prediction model has been determined to be unsuitable. It is often the case that such users create new base data, or that they have equipment for generating data to be added to the already existing base data (e.g., a calorimeter). Such users respond by, based on the notification at Step 100, performing processes such as switching the base data to be used with other preexisting base data, creating and using new base data to be used, creating new data to add to the base data to be used, or switching the color prediction model to be used to a different color prediction model. Then, when necessary, the user makes the system perform base data determination processing again and after confirming that the new base data and color prediction model to be used is a suitable combination, the user makes the system perform color conversion processing with the color management system (FIG. 4), whereby suitable color conversion can be performed with the color conversion processing.

If the determination at Step 102 is affirmative, the routine moves to Step 104 and an email whose text was selected or registered in advance is sent to a sending destination registered in advance, after which base data determination processing ends. Examples of the email that can be sent at Step 104 include a request email, which notifies that a determination has been made that the combination of the base data and the color prediction model is unsuitable while requesting the submission of new base data suitable for the color prediction model, or a question email, which notifies that a determination has been made that the combination of the base data and the color prediction model is unsuitable while asking how to respond to the determination result. Further, the sending destination for the email can be a manufacturer of input or output devices relating to color conversion, an industry the user belongs to or another person in an organization, or other people on an online community site that the user is registered on.

Users that use the above-described email sending function tend to have a lack of knowledge relating to base data and color prediction model and of know-how regarding solutions for responding to cases where the combination of the base data and color prediction model has been determined to be unsuitable. It is often the case that such users do not have the equipment for making new base data or generating data to be added to the already existing base data. By sending the above-described request email or question email, the user can receive instructions regarding how to deal with the determination result or receive submissions of new base data. The user can follow the instructions and perform processes such as switching the base data to be used with other preexisting base data, switching the color prediction model to be used with a different color prediction model, and switching the base data to be used with the new submitted base data.

Then, base data determination processing can be performed as necessary and after it has been confirmed that the new base data and color prediction model to be used are a suitable combination, color conversion processing (FIG. 4) can be performed with the color management system, whereby appropriate color conversion can be performed with the color conversion processing. Accordingly, even if the user is one who lacks knowledge and know-how and who does not have equipment such as a calorimeter, that user can easily perform tasks for performing appropriate color conversion by using the above-described email sending function. Note that Step 104 acts as the informing unit in the embodiment of the present invention.

Note that in the above, when the precision of the base data to be used is determined to be low, by performing exclusion of a portion of data from the base data or processing for calculation of color difference (Steps 82-88 in FIG. 5) for each portion of color region, the performance of extraction of the low-precision portion of color region is combined therewith. Nonetheless, the present invention is not thus limited. The invention can be configured so that only determination regarding whether the designated base data and color prediction model to be used are a suitable combination, and the extraction of low-precision portion of color region can be omitted.

### Second Embodiment

Next, the second embodiment of the present invention will be explained. Note that each of the embodiments explained below has the same configuration as in the first embodiment so each portion has the same code number and explanations on the configurations will be omitted. With regard to the base data determination processing according to each embodiment, explanations will be made only for portions that differ from the base data determination processing of embodiments that have already been explained.

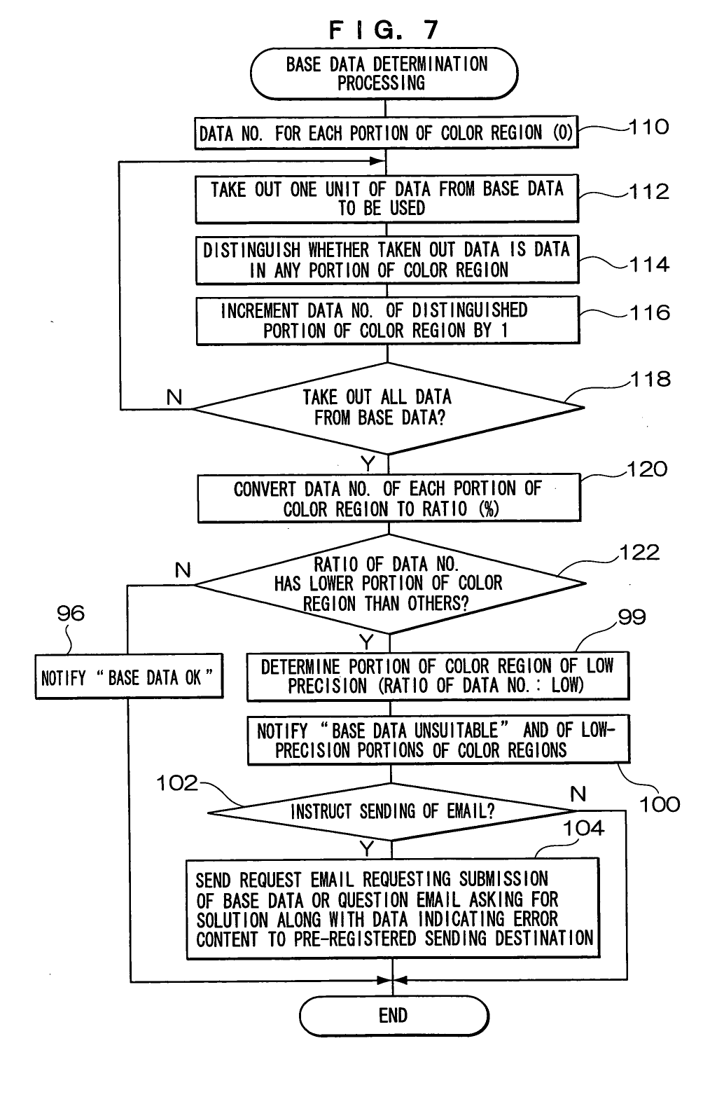

In the base data determination processing (FIG. 5) explained in the first embodiment, determination regarding whether the combination of base data and a color prediction model designated for use is suitable and extraction of a low-precision portion of color region are performed based on the color difference of each portion of color region when a portion of data is excluded from the base data to be used. However, in the base data determination processing according to the second embodiment (FIG. 7), the above-described determination and extraction are performed based on the number of data corresponding to each individual portion of color region among the data forming the base data to be used.

That is, first, at Step 110, the data numbers corresponding to each portion of color region each having an initial setting of 0. At Step 112, the base data for use designated by the user as base data used in color conversion (and the generation of the profile therefor) is recognized, and after acquiring the recognized base data to be used from the base data DB, a single piece of data is taken out from the acquired base data to be used (i.e., a set of a first color value and second color value corresponding to a specific color). At the next Step 114, a determination is made as to whether the data taken out at Step 112 is the data that corresponds to a color in any of the portion of color regions. Then at Step 116, the data number corresponding to the portion of color region distinguished at Step 114 is incremented by 1. At Step 118, it is determined whether all of the data was retrieved from the base data to be used. When the determination is negative, the routine returns to Step 112 and Steps 112-118 are repeated until the determination at Step 118 becomes affirmative. Due to this, the number of data corresponding to each portion of color region included in the base data to be used becomes counted at each portion of color region.

When the above-described counting is finished, the determination at Step 118 becomes affirmative, the routine moves to Step 120, and the data number of each individual portion of color region is divided by the total number of data forming the base data to be used (i.e., by the total number of sets of first color value and second color value), whereby the result is converted into a ratio of data corresponding to each individual portion of color region that occupies data forming the base data to be used for data numbers of each portion of color region. Then at the next Step 122, it is determined whether a portion of color region exists where the data ratio obtained at Step 120 is lower than above a predetermined %. As previously mentioned, there is a correlation between the amount of data forming the base data and the precision of color conversion carried out using that base data. When there is a bias in the number of data corresponding to each portion of color region included in the base data to be used, there is a high probability that the precision of color conversion will be insufficient in particular portion of color regions where the number of corresponding data is low. With the base data determination processing according to the second embodiment, the ratio of the data corresponding to each portion of color region is compared at Step 122 based on the above, whereby it is determined whether the base data and color prediction model designated for use are a suitable combination.

The above-described determination does not consider whether the numbers of the data for each individual portion of color region required by the color prediction model for use are sufficient. For this reason, when compared to the base data determination processing explained in the first embodiment, the accuracy of determination regarding color conversion precision is slightly lower. However, the process becomes simpler because determination can be performed by simply counting the number of data for each individual portion of color region. Note that the system can be made so that it is also determined at Step 122 whether the total number of data that forms the base data to be used is at or above a threshold, and when that determination is negative, it judges that the combination of base data and color prediction model is unsuitable. Further, the system can be made so that, in the determination at Step 122, the number of data corresponding to each individual portion of color region can be used in place of the ratio of the data corresponding to each individual portion of color region in order to determine whether the smallest value from among the data corresponding to each individual portion of color region is at or above a first threshold, or to determine whether the standard deviation (or dispersion) of the number of data corresponding to each individual portion of color region is less than a second threshold; whereby it can be determined whether the base data and the color prediction model are a suitable combination. Note that Steps 110-122 correspond to the determining sector according to the present invention.

When the determination at Step 122 is negative, the routine moves to Step 96 and, as in the first embodiment, the system notifies the user that the combination of base data and color prediction model is a suitable combination, and then base data determination processing is finished. If, however, the determination at Step 122 is affirmative, the routine moves to Step 99 and the system extracts a portion of color region where the ratio of corresponding data calculated at Step 120 for a low-precision portion of color region where it is estimated that the precision of color conversion will be low. Note that when extracting only one low-precision portion of color region, it is only necessary to extract the portion of color region where the data ratio is the smallest. When extracting a predetermined multiple number of low-precision portion of color regions, it is only necessary to select a predetermined number of portion of color regions in the ascending order of the data ratios. If the number of extracted low-precision portion of color regions is indeterminate, all of the portion of color regions where the data ratios are, for example, below a threshold can be extracted.

Note that as in the first embodiment, the process can be set so that when the low-precision portion of color regions extracted at Step 99 are only the regions where the degree of involvement with the precision of color conversion is slight, and it is determined that the base data and color prediction model designated for use are a suitable combination, then the routine moves to Step 96. Further, the processing after the next Step 100 is the same as the base data determination processing according to the first embodiment, so explanations thereon will be omitted. Steps 110-120 and Step 99 in the base data determination processing according to the second embodiment correspond to the low-precision region detector of the embodiment of the present invention. More specifically, it corresponds to a low-precision region detector that “as the low-precision portion of color regions, detects portion of color regions where the number of corresponding data is less than other portion of color regions”.

### Third Embodiment

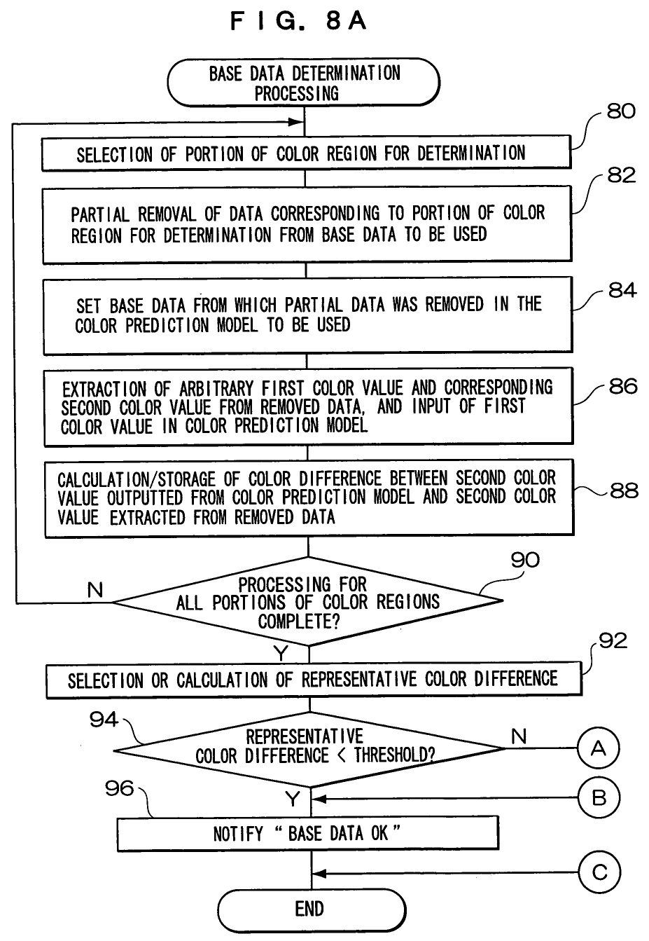

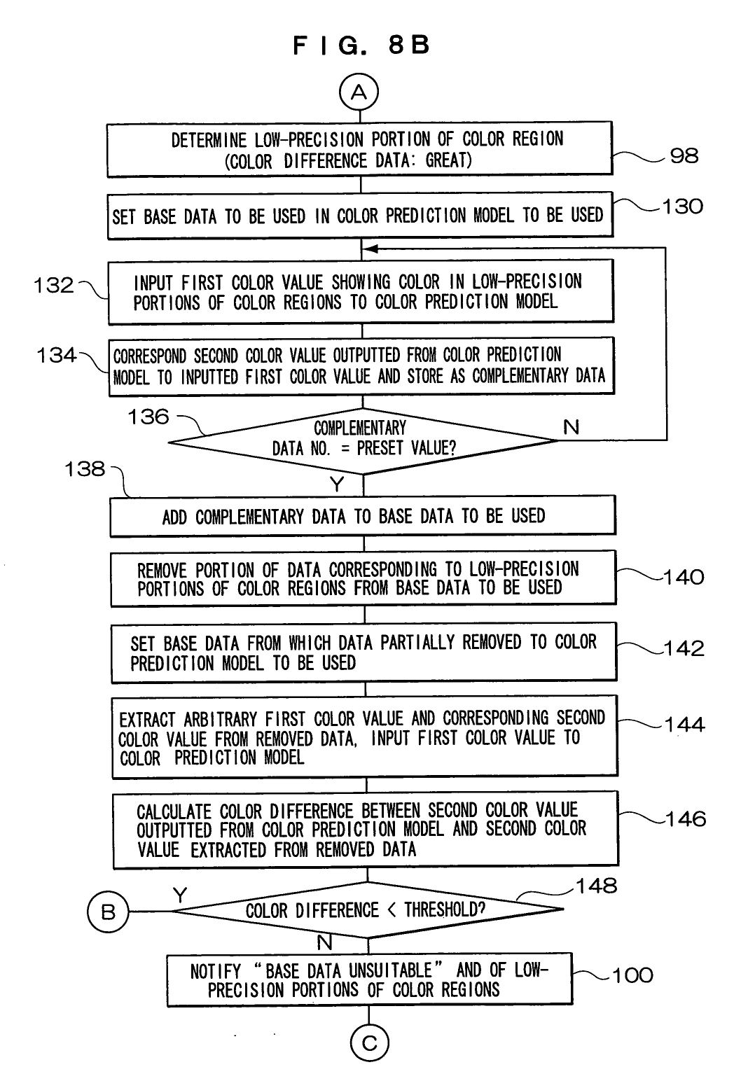

Next, the third embodiment of the present invention will be explained. In the base data determination processing explained in the first and second embodiments (FIGS. 5 and 7), when it is determined that the base data and color prediction model designated for use are an unsuitable combination, the user is notified by the sending of a request email or question email. However, in the base data determination processing according to the third embodiment (FIGS. 8A and 8B), processing is performed where complementary data that complements the base data for use is automatically generated and added to the base data for use.

That is, in the base data determination processing according to the third embodiment, the determination at Step 94 is negative because the representative color difference is at or above the threshold (i.e., it was determined that the base data and the color prediction model were an unsuitable combination) so when the low-precision portion of color region is extracted at Step 98, the base data to be used (the original base data where a portion of the data has not been excluded) is set in the color prediction model to be used at the next Step 130. At the next Step 132, a first color value representing an arbitrary color within the low-precision portion of color region extracted at Step 98 is inputted to the color prediction model in which the base data is set at Step 130. Then at Step 134, a second color value outputted from the color prediction model in accompany with the inputting of the first color value in Step 132 is made to correspond with the above-described first color value, and is stored in the memory 14B as complementary data that complements the low-precision portion of color region data in the base data to be used.

At Step 136, it is determined whether complementary data of a predetermined number is accumulated in the memory 14B. Note that the above-described predetermined number can be a fixed value, or can be changed in accordance with deviations between the representative color difference and the threshold compared at Step 94 (so that as the deviation increases, the value of the predetermined number increases). When the determination at Step 136 is negative, the routine returns to Step 132 and Steps 132-136 are repeated until the determination at Step 136 becomes affirmative. Then when the predetermined number of complementary data is accumulated in the memory 14B, the determination at Step 136 becomes affirmative and the routine moves to Step 138 and the complementary data accumulated in the memory 14B is added to the base data to be used.

As described above, in the third embodiment, base data and color prediction model to be used that are determined to be an unsuitable combination are used to request complementary data. The color prediction model is a model where the outputted color value corresponding to the inputted inputted color value can be obtained by conducting estimation calculations performed thereon with various algorithms when an unknown inputted color value is inputted based on set base data. The above-described algorithms interpolate between each of the data forming the set base data. Then the algorithms convert the inputted color value to an outputted color value with conversion characteristics that are suitable with the fact that smoothing is performed over the entirety. Accordingly, instead of generating a profile using, as is, base data and a color prediction model that are an unsuitable combination, the above-described base data and color prediction model are used and complementary data that complements low-precision portion of color region data is generated. By adding this to the generated base data to be used, the base data and color prediction model to be used are used and the precision of color conversion in low-precision portion of color region of the color conversion conditions (profile) can be improved.

At the next Steps 140-148, a determination is made only for the low-precision portion of color region regarding the suitability of the combination of the color prediction model and base data to be used to which the complementary data is added, as in Steps 82-94. That is, first, a portion of the data corresponding to the low-precision portions of color regions is excluded from the base data to which the complementary data is added (Step 140); the base data from which a portion of the data corresponding to the low-precision portions of color regions is excluded is set in the color prediction model to be used (Step 142); a set of a second color value corresponding to an arbitrary first color value is extracted from the portion of data corresponding to the low-precision portions of color regions excluded previously from the base data, and the extracted first color value is inputted to the above-described color prediction model (Step 144). Then the color difference between the second color value extracted at Step 144 and the second color value outputted from the color prediction model in accompany with the inputting of the first color value to the color prediction model is calculated (Step 146); and then it is determined whether the calculated color difference is below a threshold (Step 148).

When the determination at Step 148 is affirmative, it can be determined whether the precision of color conversion in the low-precision portions of color regions has reached a sufficient level in accompany with the adding of complementary data to the base data to be used, so the routine moves to Step 96 and the system notifies the user that the combination of the base data and color prediction model is a suitable one, and base data determination processing finishes. Note that the system can be designed so that when addition of complementary data to base data to be used is performed, it also notifies the user that complementary data is added. Further, in the case where the determination at Step 148 is negative, it can be determined that, despite the addition of the complementary data to the base data to be used, a sufficient level of color conversion precision in the low-precision portions of color regions has not been reached. Accordingly, at Step 100, the fact that the combination of the base data and color prediction model is unsuitable is notified to the user while notifying the user also of the low-precision portions of color regions, and then base data notification processing is ended.

Note that in the base data determination processing according to the third embodiment, Steps 80-92 and Step 98 correspond to the low-precision portions of color regions detector in the embodiment of the present invention. More specifically, these correspond to a low-precision portions of color regions detector that “detects a portion of color region where the color difference is larger than other portion of color regions as the low-precision portions of color regions”. Steps 130-138 correspond to the acquisition unit in the embodiment of the present invention.

In this manner, with the base data determination processing according to the third embodiment, when it is determined that the combination of the base data and color prediction model designated for use is unsuitable, the generation of complementary data and its addition to the base data is automatically performed so that suitable color conversion can be performed. Accordingly, the precision of color conversion in a low-precision portions of color regions can be improved due to the addition of this complementary data, and suitable color conversion conditions (profile) can be obtained from the combination of the designated base data and color prediction model. Accordingly, when the combination of the base data and color prediction model designated for use by the user is unsuitable, the burden placed on the user to obtain suitable color conversion conditions can be alleviated.

### Fourth Embodiment

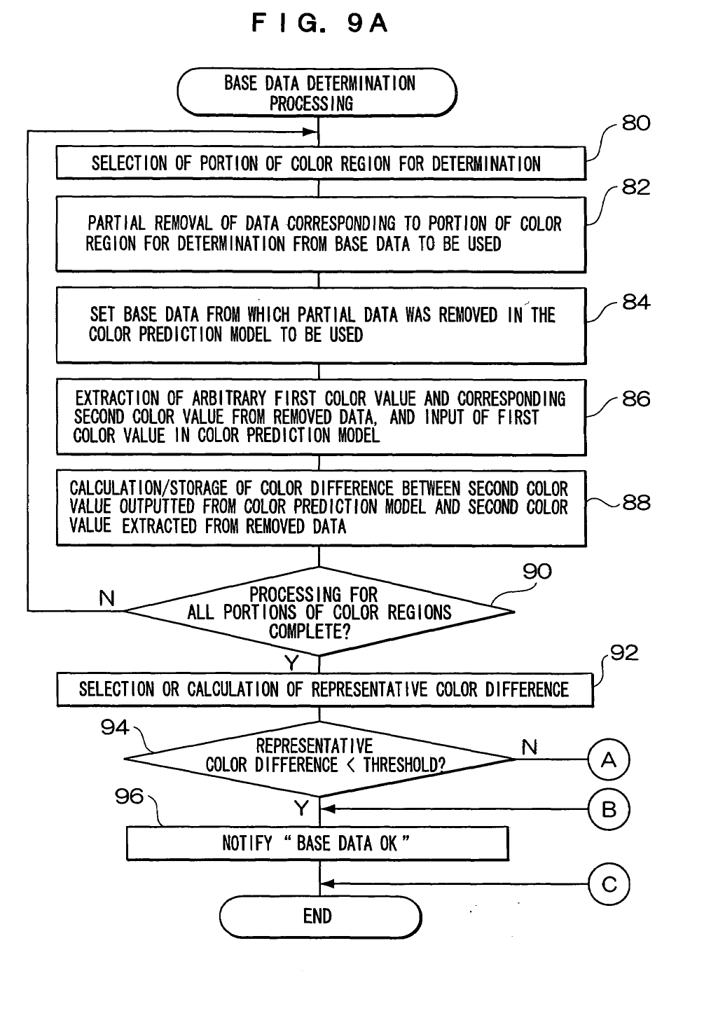

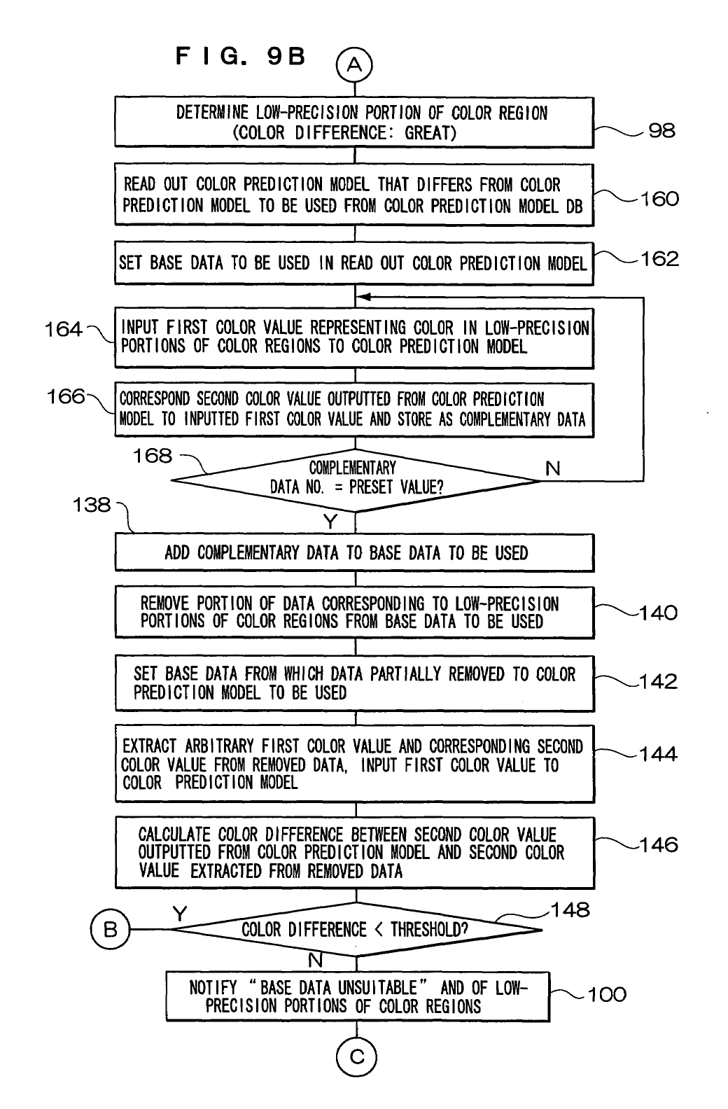

Next, the fourth embodiment of the present invention will be explained. The base data determination processing according to the fourth embodiment (FIGS. 9A and 9B) differs from the third embodiment in that complementary data is generated using a color prediction model that differs from the color prediction model to be used.

That is, with the base data determination processing according to the fourth embodiment, the determination at Step 94 is negative because the representative color difference is at or above the threshold (i.e., it is determined that the base data and color prediction model are an unsuitable combination) so when the low-precision portions of color regions is extracted at Step 98, an arbitrary color prediction model that differs from the color prediction model to be used is read out from the color prediction model DB at the next Step 160. Note that for the color prediction model read out at Step 160, an arbitrary color prediction model can be applied and can also be a physical model such as Neugebauer and Kubelka-Munk. At Step 162, base data to be used is set in the color prediction model read out at Step 160 and at the next Step 164, a first color value representing an arbitrary color in the low-precision portions of color regions extracted at Step 98 is inputted to the color prediction model to which base data is set in Step 162.

Then at Step 166, a second color value outputted from the color prediction model in accompany with the inputting of the first color value in Step 164 is made to correspond with the above-described first color value and is stored in the memory 14B as complementary data that complements the low-precision portions of color regions data in the base data to be used. At Step 168, it is determined whether a predetermined number of complementary data is accumulated in the memory 14B. Note that the above-described predetermined number can be a fixed value, or can be made to change in accordance with deviations between the representative color difference and the threshold compared at Step 94 (so that as the deviation increases, the value of the predetermined number increases). When the determination at Step 168 is negative, the routine returns to Step 164 and Steps 164-168 are repeated until the determination at Step 168 becomes affirmative. Then when the predetermined number of complementary data is accumulated in the memory 14B, the determination at Step 168 becomes affirmative and the routine moves to Step 138 and the complementary data accumulated in the memory 14B is added to the base data to be used. Note that the processing from the next Step 140 onward is the same as the base data determination processing according to the third embodiment so explanations thereon will be omitted.

Note that in the base data determination processing according to the fourth embodiment, Steps 80-92 and Step 98 correspond to the low-precision portions of color regions detector in the embodiment of the present invention. More specifically, these correspond to a low-precision portions of color regions detector that “detects a portion of color region as the low-precision portions of color regions where the color difference is larger than other portion of color regions”. Steps 160-168 and Step 138 correspond to the acquisition unit in the embodiment of the present invention.

In this manner, with the base data determination processing according to the fourth embodiment, when it is determined that the combination of the base data and color prediction model designated for use is unsuitable, the generation of complementary data and its addition to the base data is automatically performed so that suitable color conversion can be performed, just as in the third embodiment. Accordingly, the precision of color conversion in a low-precision portions of color regions can be improved due to the addition of this complementary data, and suitable color conversion conditions (profile) can be obtained from the combination of the designated base data and color prediction model.

Further, in the color prediction model, there are portions of color regions with excellent interpolation capabilities and portions of color regions with inferior interpolation capabilities, and this is due to the characteristics of the algorithms. The algorithms employed by each individual color prediction model differ from each other so the color regions with excellent interpolation capabilities and the color regions with inferior interpolation capabilities are also different for each color prediction model. For this reason, when combining the base data to be used with the color prediction model to be used, the chances of being able to obtain suitable data that can achieve high-precision color conversion as the above-described portion of color region data (complementary data) are improved, even if the portion of color region is one where it has been determined that the low-precision portions of color regions is one where the color conversion precision is low. This is made possible by setting the base data to be used in a color prediction model that differs from the color prediction model to be used and requesting complementary data, as in the present embodiment. Accordingly, when the combination of the base data and color prediction model designated for use by the user is unsuitable, the chances of being able to obtain suitable color conversion conditions (profile) from the combination can be made to improve and in this case, the burden placed on the user to obtain suitable color conversion conditions can be further alleviated.

### Fifth Embodiment

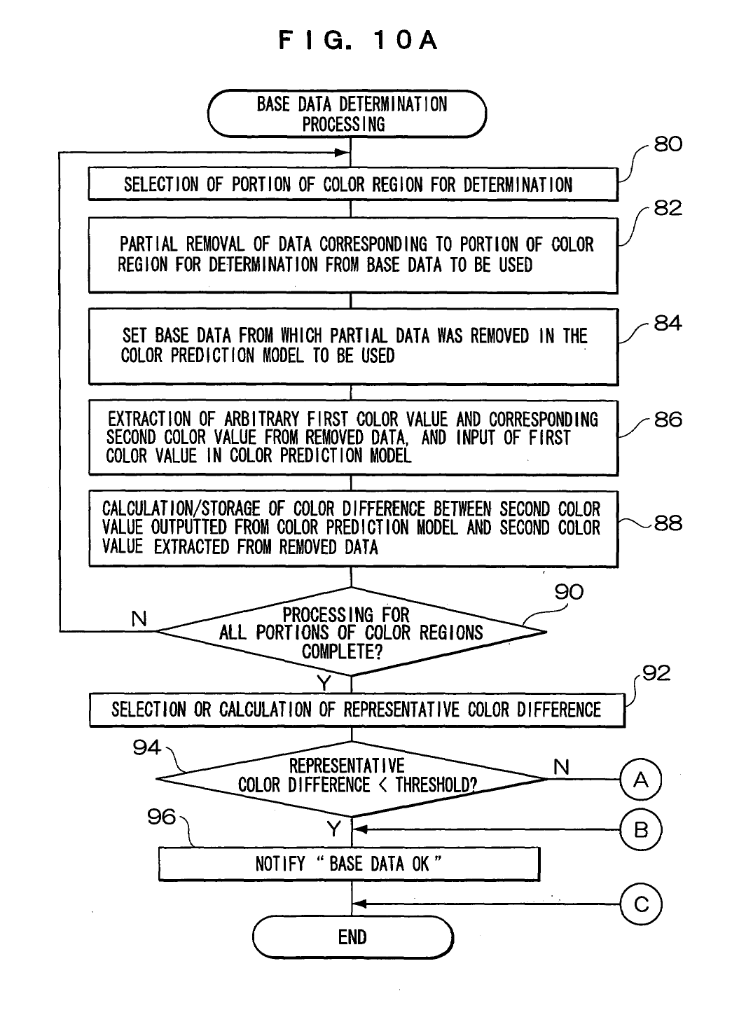

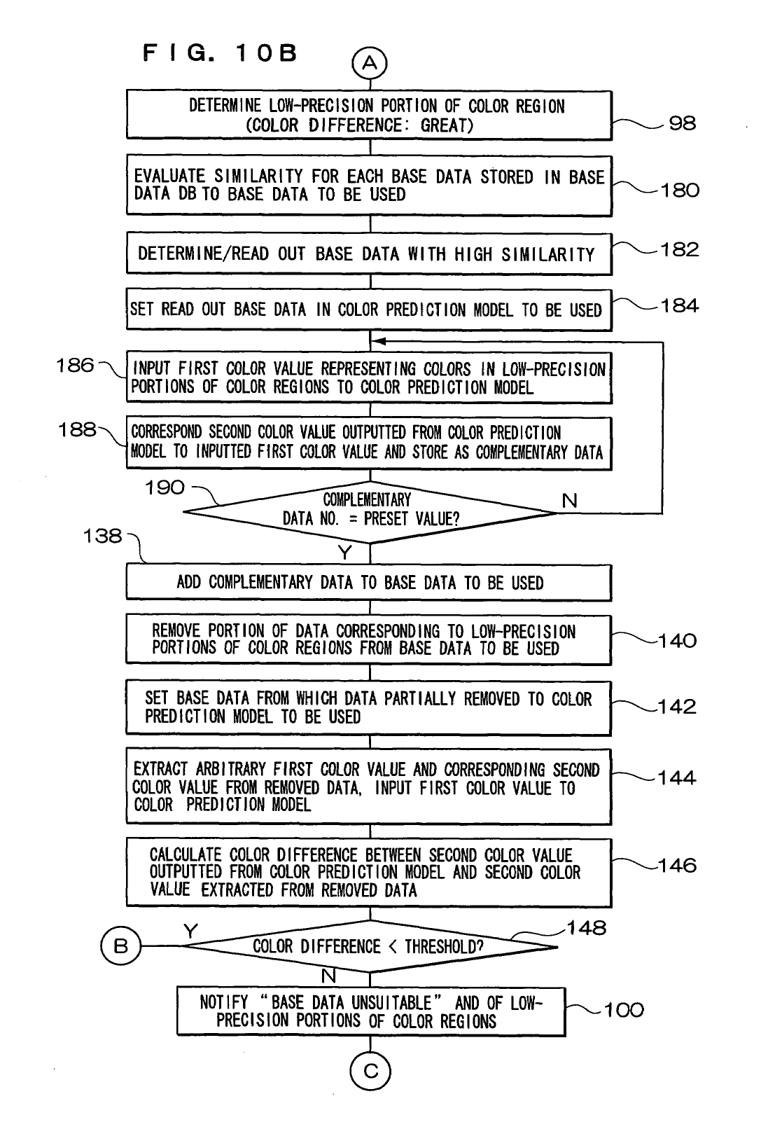

Next, the fifth embodiment of the present invention will be explained. The base data determination processing according to the fifth embodiment (FIGS. 10A and 10B) differs from the third and fourth embodiments in that complementary data is generated using base data that differs from the base data to be used.

That is, with the base data determination processing according to the fifth embodiment, the determination at Step 94 is negative because the representative color difference is at or above the threshold (i.e., it is determined that the base data and color prediction model are an unsuitable combination) so when the low-precision portions of color regions is extracted at Step 98, the similarities of each base data stored in the base data DB with the base data to be used are evaluated at the next Step 180. Then, at Step 182, the base data with a high degree of similarity with the base data to be used is determined based on the evaluation results in Step 180, and that base data is read out from the base data DB.

Note that with the evaluation/determination of similarity of the base data in Steps 180 and 182, multiple sets of first and second color values corresponding to, for example, the base data to be used can be extracted as standard values, after which specified base data is set in a constant color prediction model. The multiple first color values extracted as standard values are sequentially inputted to the color prediction model in which the specified base data was set. With regard to the second color values sequentially outputted from the color prediction model, the color difference of the second color values corresponding to the first color values inputted to the color prediction model as the standard values are each calculated and stored. Calculation of representative color differences (e.g., the average value of the color differences) from the multiple obtained color differences is performed for each individual base data stored in the base data DB. This can be performed by selecting the base data where the representative color difference is smallest as the base data whose similarity with the base data to be used is greatest.

Also, the characteristic features of the input device and output device fluctuate and change both over time and periodically. In order to absorb (correct) change of characteristic features that occurs both over time and periodically with color conversion, there are cases where the base data corresponding to the same device are each created at timing that differs from that of the characteristic features of the device, and each of these are stored in the base data DB. The system can be set so that base data created when the characteristic features are the same or similar with the current device can be fudged with base data that has a high degree of similarity with the base data to be used so, as described above, multiple base data corresponding to the same device are stored in the base data DB. Further, when the cycles of the changes in characteristic features of the device are known in advance, based on the cycles of the changes in characteristic features of the device, the period estimated during which the characteristic features of the device are the same as those of the current device is found. Thus, the system can be designed so as to determine that the base data created at that determined period or the period closest thereto is the base data whose similarity with the base data to be used is greatest.

At Step 184, the base data read out at Step 182 is set in the color prediction model to be used and at the next Step 186, and the first color value representing an arbitrary color within the low-precision portion of color region extracted at Step 98 is inputted to the color prediction model in which the base data is set at Step 184. Then at Step 188, a second color value outputted from the color prediction model in accompany with the inputting of the first color value in Step 186 is made to correspond with the above-described first color value, and is stored in the memory 14B as complementary data that complements the low-precision portion of color region data in the base data to be used. At Step 190, it is determined whether a predetermined number of complementary data is accumulated in the memory 14B. Note that the above-described predetermined number can be a fixed value, or can be made to change in accordance with deviations between the representative color difference and the threshold compared at Step 94 (so that as the deviation increases, the value of the predetermined number increases).

When the determination at Step 190 is negative, the routine returns to Step 186 and Steps 186-190 are repeated until the determination at Step 190 becomes affirmative. Then when the predetermined number of complementary data is accumulated in the memory 14B, the determination at Step 190 becomes affirmative and the routine moves to Step 138 and the complementary data accumulated in the memory 14B is added to the base data to be used. Note that the processing from the next Step 140 onward is the same as the base data determination processing according to the third embodiment so explanations thereon will be omitted.

Note that in the base data determination processing according to the fifth embodiment, Steps 80-92 and Step 98 correspond to the low-precision portions of color regions detector in the embodiment of the present invention. More specifically, these correspond to a low-precision portions of color regions detector that “detects a portion of color region as the low-precision portions of color regions where the color difference is larger than other portion of color regions”. Steps 180-190 and Step 138 correspond to the acquisition unit in the embodiment of the present invention.

In this manner, with the base data determination processing according to the fifth embodiment, when it is determined that the combination of the base data and color prediction model designated for use is unsuitable, the generation of complementary data and its addition to the base data is automatically performed so that suitable color conversion can be performed, just as in the third and fourth embodiments. Accordingly, the precision of color conversion in a low-precision portions of color regions can be improved due to the addition of this complementary data, and it becomes possible for suitable color conversion conditions (profile) to be obtained from the combination of the designated base data and color prediction model. Further, with the fifth embodiment, base data that is determined to have a high degree of similarity with the base data to be used is found, and this base data with a high degree of similarity is set in the color prediction model to be used, and complementary data is sought, so it is very likely that suitable data that can achieve high-precision color conversion will be obtained as the complementary data. Accordingly, when the combination of the base data and color prediction model designated for use by the user is unsuitable, the chances of being able to obtain suitable color conversion conditions (profile) from the combination can be improved and in this case, the burden placed on the user to obtain suitable color conversion conditions can be further alleviated.

### Sixth Embodiment

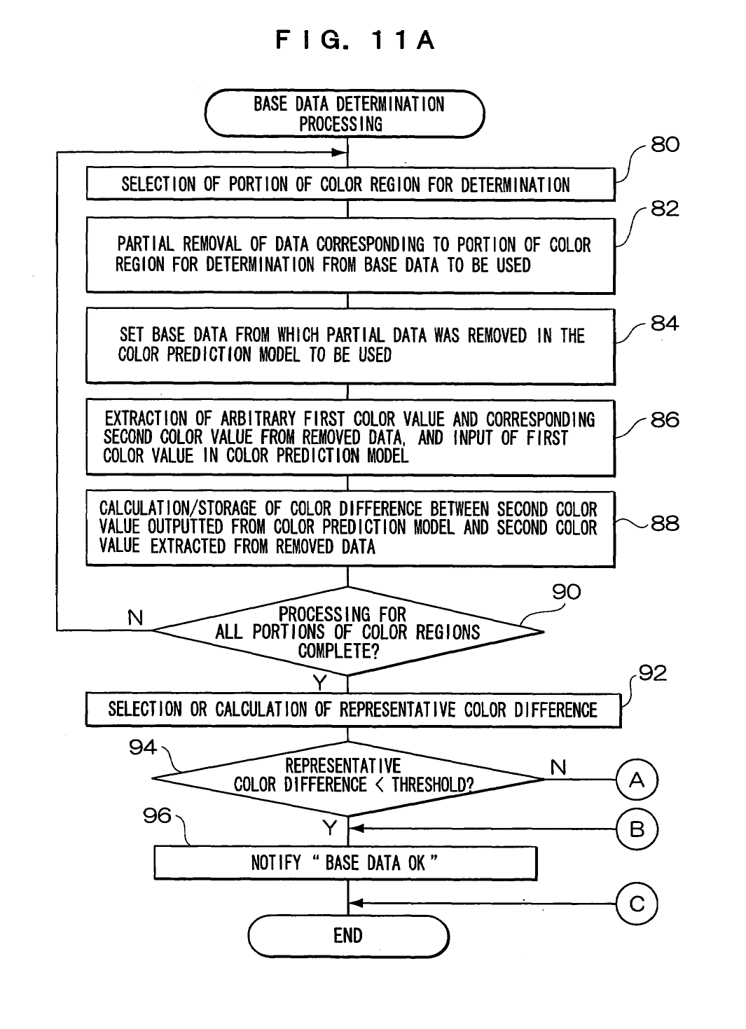

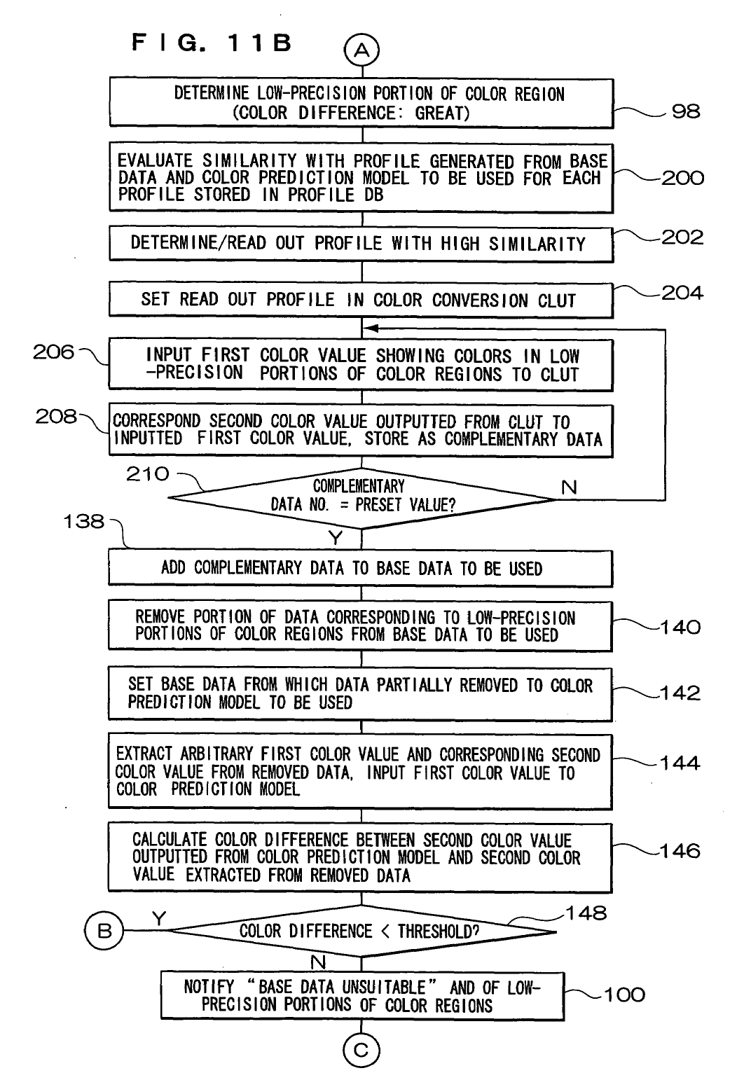

Next, the sixth embodiment of the present invention will be explained. The base data determination processing according to the sixth embodiment (FIGS. 11A and 11B) differs from the third through fifth embodiments in that complementary data is generated using a profile that differs from the profile generated from the base data and color prediction model to be used.

That is, with the base data determination processing according to the sixth embodiment, the determination at Step 94 is negative because the representative color difference is at or above the threshold (i.e., it is determined that the base data and color prediction model are an unsuitable combination) so when the low-precision portions of color regions is extracted at Step 98, the similarities of each profile stored in the profile DB are evaluated at Step 200 with the profile generated from the base data and color prediction model to be used (for the sake of convenience, hereafter referred to as “standard profile”). At Step 202, the profile having a high degree of similarity with the sprofile is determined based on the similarity evaluation results in Step 200, and that profile is read out from the profile DB.

Note that with the profile similarity evaluation/determination in Steps 200 and 202, for example, standard profile is set in a color conversion CLUT, multiple first color values are sequentially inputted to the CLUT in which the standard profile was set, and with the inputting of the first color values, the second color values sequentially outputted from the CLUT are made to correspond with the first color values, and these are stored as standard data, after which a specified profile is set in the CLUT. The multiple first color values stored as standard data are sequentially inputted to CLUT in which the specified profile was set. With regard to the second color values sequentially outputted from the CLUT, the color difference of the second color values stored as standard data each calculated and stored. Calculation of representative color differences (e.g., the average value of the color differences) from the multiple obtained color differences is performed for each individual profile stored in the profile DB. The profile with the smallest representative color difference can be selected as the profile with the greatest degree of similarity with the standard profile.

Note that, by setting the standard profile in the CLUT and inputting the first color values as described above, the system can be configured so that the sets of the first and second color values set in the standard profile are extracted as is from the standard profile as standard data, rather than acquiring the first and second color values as standard data.

At Step 204, the profile read out at Step 202 is set in the color conversion CLUT and at the next Step 206, the first color value representing an arbitrary color within the low-precision portion of color region extracted at Step 98 is inputted to the CLUT in which the profile was set at Step 204. Then at Step 208, a second color value outputted from the color prediction model in accompany with the inputting of the first color value in Step 206 is made to correspond with the above-described first color value, and is stored in the memory 14B as complementary data that complements the low-precision portion of color region data in the base data to be used. At Step 210, it is determined whether a predetermined number of complementary data is accumulated in the memory 14B. Note that the above-described predetermined number can also be made to change in accordance with deviations between the representative color difference and the threshold compared at Step 94 (so that as the deviation increases, the value of the predetermined number increases).

When the determination at Step 210 is negative, the routine returns to Step 206 and Steps 206-210 are repeated until the determination at Step 210 becomes affirmative. Then when the predetermined number of complementary data is accumulated in the memory 14B, the determination at Step 210 becomes affirmative and the routine moves to Step 138 and the complementary data accumulated in the memory 14B is added to the base data to be used. Note that the processing from the next Step 140 onward is the same as the base data determination processing according to the third embodiment so explanations thereon will be omitted.

Note that in the base data determination processing according to the sixth embodiment, Steps 80-92 and Step 98 correspond to the low-precision portions of color regions detector in the embodiment of the present invention. More specifically, these correspond to a low-precision portions of color regions detector that “detects a portion of color region as the low-precision portions of color regions where the color difference is larger than other portion of color regions”. Steps 200-210 and Step 138 correspond to the acquisition unit in the embodiment of the present invention.

In this manner, with the base data determination processing according to the sixth embodiment, when it is determined that the combination of the base data and color prediction model designated for use is unsuitable, the generation of complementary data and its addition to the base data is automatically performed so that suitable color conversion can be performed, just as in the third through fifth embodiments. Accordingly, the precision of color conversion in a low-precision portions of color regions can be improved due to the addition of this complementary data, and it becomes possible for suitable color conversion conditions (profile) to be obtained from the combination of the designated base data and color prediction model. Further, with the sixth embodiment, profile that is determined to have a high degree of similarity with the profile (standard profile) generated from the base data and color prediction model to be used is found, and this profile with a high degree of similarity is set in the CLUT, and complementary data is sought, so it is very likely that suitable data that can achieve high-precision color conversion will be obtained as the complementary data. Accordingly, when the combination of the base data and color prediction model designated for use by the user is unsuitable, the chances of being able to obtain suitable color conversion conditions (profile) from the combination can be improved and in this case, the burden placed on the user to obtain suitable color conversion conditions can be further alleviated.

### Seventh Embodiment

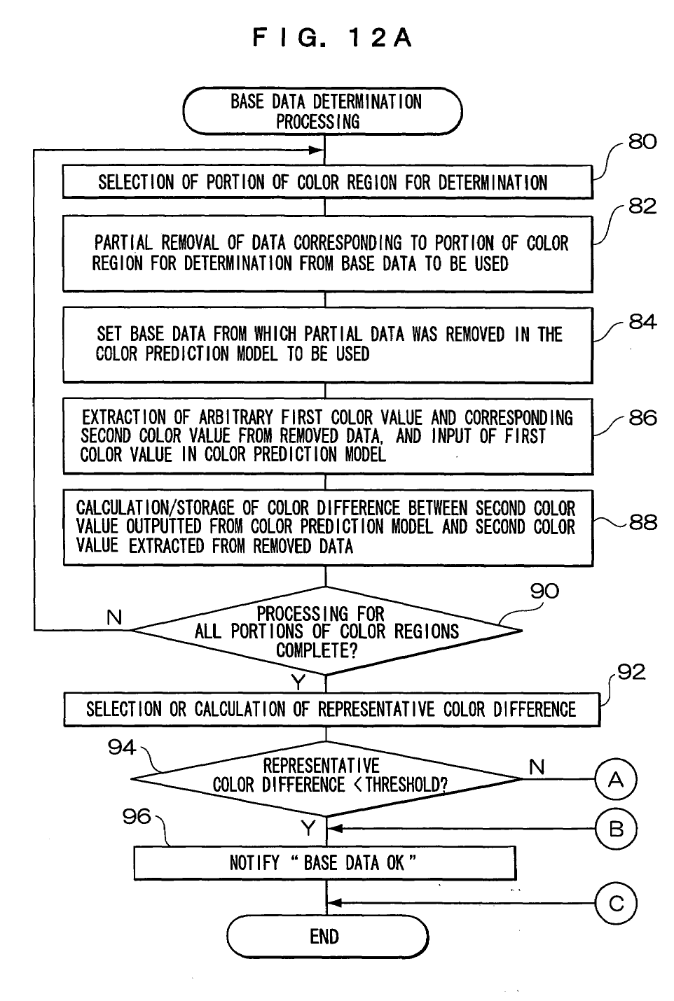

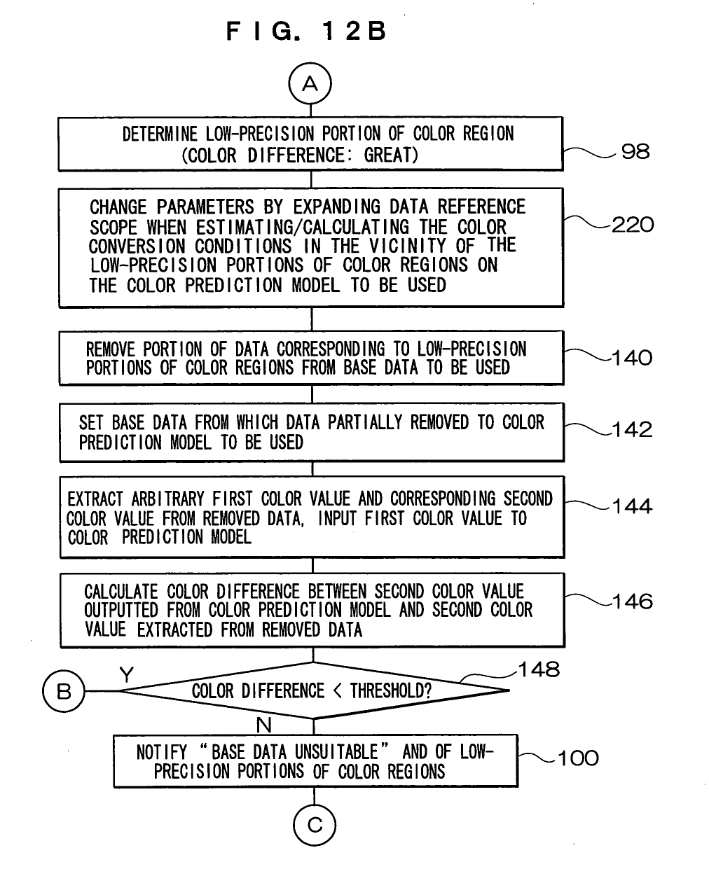

Next, the seventh embodiment of the present invention will be explained. The base data determination processing according to the seventh embodiment (FIGS. 12A and 12B) differs from the third through sixth embodiments in that rather than generating complementary data, the parameters of the color prediction model are changed.

For the color prediction model algorithms, generally a data reference region of predetermined size is set at a specified position in an inputted color space (the color space of the inputted color value) as the center of that specified position. Estimation calculations of the color conversion conditions (the relation between the inputted color value and outputted color value) in the specified region and the vicinity thereof is performed for each position in the inputted color space, whereby an algorithm is employed that estimates and calculates the relation between the inputted color value and outputted color value with regard to the entire region within the inputted color space. For this reason, in the base data set in the color prediction model, when the number of data representing colors in the data reference region, where a given position in the inputted color space is set as the center, is insufficient, the color conversion conditions generated by the color prediction model are such that the precision of the color conversion in the given position and the vicinity thereof deteriorates. Also, if the size of the data reference region is enlarged in this case, the number of data referred to increases when estimating/calculating the color conversion conditions in the given position and the vicinity thereof, whereby the precision of the generated color conversion conditions is improved.

Based on the above, with the base data determination processing according to the seventh embodiment, the determination at Step 94 becomes negative because the representative color difference is at or above the threshold (i.e., it is determined that the base data and color prediction model are an unsuitable combination) so when the low-precision portions of color regions is extracted at Step 98, the parameters in the color prediction model to be used are changed in the next Step 220 so that estimation calculation is performed for the color conversion conditions in the low-precision portions of color regions vicinity, upon which the size of the data reference scope is enlarged. Then the processing from Step 140 on is the same as the base data determination processing according to the third embodiment, so explanations thereon will be omitted. The only point that differs is that in Step 142, base data in which a portion of data corresponding to the low-precision portions of color regions has been excluded is set in the color prediction model to be used whose parameters were changed at Step 220. Further, in the seventh embodiment, the color prediction model whose parameters are changed at Step 220 can also be used when generating a profile with the color conversion processing by the color management system (FIG. 4).

In the base data determination processing according to the seventh embodiment, Steps 80-92 and Step 98 correspond to the low-precision region detector in recitations of the embodiment of the present invention. More specifically, these correspond to a low-precision region detector that “detects a portion of color region as the low-precision portions of color regions where the color difference is larger than other portion of color regions”. Step 200 corresponds to the expander.

In this manner, with the base data determination processing according to the seventh embodiment, when it is determined that the combination of the base data and color prediction model designated for use is unsuitable, and estimation/calculation is performed for color conversion conditions in the vicinity of the low-precision partial regions, the parameters of the color prediction model to be used are changed so that the size of the reference scope is enlarged. Accordingly, when the color conversion conditions (the relation between the first and second color values) are estimated and calculated with the color prediction model in the low-precision portions of color regions and the vicinity thereof, the color conversion conditions become such that they are estimated and calculated based on a greater number of data. This means that the precision of the color conversion conditions in the low-precision portions of color regions and the vicinity thereof can be improved. Accordingly, when the combination of the base data and color prediction model designated for use by the user is unsuitable, the chances of being able to obtain suitable color conversion conditions (profile) from the combination can be made to improve and in this case, the burden placed on the user to obtain suitable color conversion conditions can be further alleviated.

Note that in the base data determination processing explained in the third through seventh embodiments, determination regarding whether the base data and color prediction model are suitable and extraction of the low-precision portions of color regions are performed based on the color difference of each portion of color region when a portion of data was excluded from the base data to be used. In place of this however, as explained in the second embodiment as well, the determination and extraction can be performed based on the number of data corresponding to each portion of color region among data that form the base data (i.e., the ratio of data that corresponds to each portion of color region that accounts for the base data to be used). In this embodiment, the steps involving extraction of the low-precision portions of color regions (the steps corresponding to Steps 110-122 and Step 99 of the base data determination processing according to the second embodiment) correspond to the low-precision region detector in the embodiment of the present invention. More specifically, these correspond to a low-precision region detector that “detects a portion of color region as the low-precision portions of color regions where the number of corresponding data is less in than other portion of color regions”.

Also, in the base data determination processing explained in the third through seventh embodiments, these can be configured so that after notification is performed stating that the combination of base data and color prediction model are unsuitable in Step 100, a request email or question email is sent as needed, just as in Steps 102 and 104 of the base data determination processing according to the first embodiment (FIG. 5). Further, with the base data determination processing of the third through seventh embodiments, after adding complementary data to the base data to be used, the precision of color conversion is determined again at Steps 140-148 for the low-precision regions. However, the present invention is not limited to this. After adding the complementary data to the base data to be used, the system can be made so that processing finishes without the precision of color conversion in the low-precision regions being determined again. The system can be configured so that when determining again the precision of the color conversion in the low-precision regions and the precision of the color conversion in the low-precision regions is low (i.e., the color difference is at or above a threshold), the generation and addition of complementary data can be performed again.

Further, when it has been determined that the combination of base data and color prediction model for use is unsuitable, in the third through sixth embodiments, explanations are made regarding the aspect that performs processing of generation of complementary data and addition thereof to base data to be used and in the seventh embodiment, regarding the aspect that changes the parameters of the color prediction model. However, it is a given that when it is determined that the combination of base data and color prediction model for use is unsuitable, each of the generation/addition of the above-described complementary data and the changes in color prediction model parameters can be performed for each of the other aspects.

Besides the above explained aspects, various alternative examples of the present invention are possible. Various aspects of the present invention will be summarized as examples below.

In the first embodiment of the present invention, base data that regulates multiple color charts for the first color value on the first color space and the second color value on the second color space that represent colors on a specified color chart and a color prediction model that estimates and calculates the relation of the first and second color values based on the base data are either inputted or designated. Examples of the first and second color spaces include a color space that depends on one side of a specified device; a uniform sensory color space that is a color space that does not depend on another device such as one recommended by, e.g., Commission Internationale de l'Eclairage (CIE) like a L*a*b* color space; the color space of a tristimulus value XYZ color coordinate system; or a color appearance model such as a CAM 02 space. Nonetheless, the present invention is not thus limited and other arbitrary color spaces are applicable.

Further, the base data generates a specified color chart based on e.g., one of a first or second color value that represents a color of a specified color chart, and measures the color of the other one of the first or second color value of the generated color chart, and can generate multiple color charts (second aspect). Also, the base data can be designated due to the fact that in a state where, e.g., a single or multiple units of base data are stored in advance in a storage unit, the base data used is designated from inside base data stored in the storage unit. The same applies to the color prediction model. The color prediction model can be designated due to the fact that in a state where, e.g., a single or multiple units of color prediction models are stored in advance in a storage unit, the color prediction model used is designated from inside color prediction models stored in the storage unit.

When base data and a color prediction model are inputted or designated, the color converting device according to the first embodiment of the present invention uses the inputted or designated base data and color prediction model to generate color conversion conditions for converting a first color value into a second color value and based on the generated color conversion conditions, performs color conversion of inputted image data. A preferable example of the above-described color conversion conditions is color conversion data (known as a “profile”) set in a color lookup table (CLUT). In this case, a CLUT in which color conversion data acting as color conversion conditions have been set is used and inputted image data is converted, whereby color conversion of image data can be performed. However, the present invention is not thus limited. For the above-described color conversion conditions, it is also possible to use the color prediction model itself in which base data has been set. In this case, the color prediction model in which base data has been set is used and the inputted image data is converted, whereby color conversion of the image data can be performed. Also, multiple 1-D lookup tables that express the gradation characteristics of a primary color or multiple colors can be used as is, or used so as to complement each other.

Here, in the above-described configuration, an arbitrary combination can be employed for the base data and color prediction model used in color conversion of image data, so, depending on the combination of the inputted or designated base data and color prediction model, there is the possibility that suitable color conversion conditions that can perform suitable color conversion will not be obtainable. For this reason, the first embodiment of the present invention is provided with a determining unit that determines whether the base data can generate suitable color conversion conditions when the inputted or designated base data is combined with the inputted or designated color prediction model. Due to this, when the combination of the inputted or designated base data and color prediction model is one where the generation of suitable color conversion conditions is difficult (i.e., an unsuitable combination), the inputted or designated base data is determined, when combined with the inputted or designated color prediction model, to be base data that cannot generate suitable color conversion conditions by a determining unit. Due to this, the fact that inputted or designated base data and color prediction model are an unsuitable combination can be detected.

Accordingly, due to the first embodiment of the present invention, the suitability of the base data and color prediction model combination used in the generation color conversion conditions can be confirmed prior to actually performing color conversion of the image data. Then, based on the determination results of the determining unit, when it has been determined that the inputted or designated base data is not the base data that can generate suitable color conversion conditions when it is combined with the inputted or designated color prediction model, processing can be performed. For example, complementary data that complements the base data can be added to the base data (will be explained later); the base data used in generating the color conversion conditions can be switched, if it is an environment where the base data can be switched; the color prediction model used in generating the color conversion conditions can be switched, if it is an environment where the color prediction model can be switched, and so on, so it becomes possible to perform suitable color conversion.

Note that in the first embodiment of the present invention, the determining unit performs determination with calculation processing as to whether the inputted or designated base data is base data that can generate the suitable color conversion conditions when combined with the inputted or designated color prediction model, by generating color conversion conditions for evaluation using data where predetermined ratio data has been excluded from the inputted or designated base data and the inputted or designated color prediction model, and with regard to the second color value obtained from the color conversion conditions for evaluation, determining whether a color difference of the second color value obtained from the generated color conversion conditions using the inputted or designated base data and color prediction model or a second color value representing the data removed from the base data is below a threshold.

In the third embodiment of the present invention, a second color value, obtained by inputting a specified first color value where a second color value corresponding to the data excluded from the base data is regulated into the evaluation color conversion conditions, can be used for the second color value obtained from the evaluation conditions. For the second color value obtained from the color conversion conditions generated using the inputted or designated base data and color prediction model, the second color value obtained by inputting a specified first color value of the above-described color conversion conditions can be used. For the second color value representing data excluded from the base data, the second color value with correspondence with the above-described specified first color value in the excluded data can be used. Further, in the first embodiment of the present invention, it is preferable that the color differences are sought for each of multiple colors. In this case, the configuration can be made so that it is determined whether the average values or greatest values or standard deviations (or dispersions) of multiple color differences are below a threshold. Further, when seeking the color differences for multiple colors, it is preferable that each color is a color dispersed and distributed in each portion of color region when the color space is divided into multiple portion of color regions. For example, when a predetermined ratio is excluded from base data with data corresponding to a specified portion of color region and a color difference is sought, the color difference for each individual portion of color region can be sought by repeating the process multiple times on a different portion of color region each time.

The color conversion conditions generated using the base data and color prediction model have certain characteristic features. When the number of data of certain color regions included in the base data is sufficient relative to the number of data necessary for the color prediction model regarding these color regions, even if new color conversion conditions are generated using base data where some of the color region data has been excluded from the original base data, precision with regard to the color regions of the newly generated color conversion conditions do not greatly deteriorate (and the color difference in the third embodiment of the present invention also remains below the threshold). In contrast, when the number of data of the color regions included in the base data is insufficient for the number of data necessary for the color prediction model, if new color conversion conditions are generated using base data where some of the color region data has been excluded from the original base data, precision with regard to the color regions of the newly generated color conversion conditions greatly deteriorate (and the color difference in the third embodiment of the present invention also exceeds the threshold).

Evaluation of the base data is generally performed by people who repeat operations such as printer output and color measurement and who, based on experience, confirm the reproducing precision of the colors. Nonetheless, with the third embodiment of the present invention, the above-described characteristic features are used and determinations are made as to whether the color difference of a second color value obtained from evaluation color conversion conditions generated using data where data of a predetermined ratio was excluded from inputted or designated base data and inputted or designated color prediction model; and a second color value obtained from color conversion conditions generated using the inputted or designated base data and color prediction model, or a second color value representing data removed from base data, is below a threshold. Accordingly, it can be determined with good accuracy whether the base data is suitable (i.e., whether sufficient data compared to the number of data that the color prediction model requires is included in the base data).

In the first embodiment of the present invention, even sufficient data compared to the number of data that the color prediction model requires is not included in the base data, if complementary data that complements the base data is added thereto, the ability to generate suitable color conversion conditions becomes possible. For example, it is preferable to further provide the device with an acquisition unit that acquires complementary data that complements the base data and adds it to the base data when it has been determined by the determining unit, at the time the inputted or designated base data is combined with the inputted or designated color prediction model, that the base data cannot generate suitable color conversion conditions. Due to this, when it has been determined at the time the inputted or designated base data is combined with the inputted or designated color prediction model that the base data cannot generate suitable color conversion conditions, the base data is redesigned so as to be able to generate suitable color conversion conditions by the addition of complementary data. Suitable color conversion conditions can be generated from the inputted or designated base data and color prediction model.

Note that acquisition of the complementary data with the acquisition unit according to a fourth aspect of the present invention can be performed such that, e.g., the unit generates or acquires a corresponding set of a first color value and second color value as the complementary data from the color conversion conditions generated using the inputted or designated base data and color prediction model.

In the fifth aspect of the present invention, when, for example, the color conversion conditions generated using the base data and color prediction model are color conversion data (a profile) set in the CLUT, the set of the corresponding first color value and second color value acting as the complementary data can be generated by inputting the first color value to the CLUT in which the above-described color conversion data was set and making the second color value outputted from the CLUT correspond to the inputted first color value. Also, the above-described color conversion data itself is data that makes a correspondence between the first and second color values with regard to each color dispersedly distributed in the color space so it is also possible to acquire (extract) the set of corresponding first and second color values from the color conversion data. When, for example, the color conversion conditions generated using the base data and color prediction model is the color prediction model itself in which the base data has been set, the set of the corresponding first and second color values functioning as the complementary data can be generated by inputting the first color value to the color prediction model having the base data and making the second color value outputted from the color prediction model correspond with the inputted first color value.

When the color conversion conditions have been generated using the base data and color prediction model, the color conversion characteristics of the generated color conversion conditions are such that interpolations are made between each of the data forming the base data and smoothing is performed of its entirety. For this reason, as in the fifth aspect of the present embodiment, when the set of corresponding first and second color values are generated or acquired as complementary data from the color conversion conditions generated using the inputted or designated base data and color prediction model, color conversion conditions that can perform more suitable color conversion can be obtained by generating color conversion conditions using the base data to which this complementary data was added.

In the fourth aspect of the present invention, when the color converting device is provided with a color prediction model storage unit that stores a plurality of color prediction models, the acquisition unit reads out a color prediction model that differs from the inputted or designated color prediction model from the plurality of color prediction models stored in the color prediction model storage unit and uses the color prediction model read out from the color prediction model storage unit and the inputted or designated base data and generates color conversion conditions for generating complementary data, and it becomes possible to generate or acquire the set of the corresponding first color value and second color value as the complementary data from the generated color conversion conditions for generating complementary data.

In this case as well, by generating color conversion conditions using base data to which the above-described complementary data has been added, color conversion conditions that can perform even more suitable color conversion can be obtained. Note that besides models that perform neural nets or statistical inference, physical models such as Neugebauer and Kubelka-Munk can also be included in the multiple color prediction models stored in the color prediction model storage unit.

Also, in the fourth aspect of the present embodiment of the present invention, when the color converting device is provided with a base data storage unit that stores a plurality of base data inputted in the past, the acquisition unit can search among base data stored in the base data storage unit for base data whose similarity with the inputted or designated base data is high, read out base data extracted by the search from the base data storage unit, and acquire the set of corresponding first color value and second color value from the read out base data as the complementary data.

In the seventh aspect of the present embodiment of the present invention, the search for base data whose similarity with the inputted or designated base data is high, after, for example, extraction of the corresponding first and second color values from the inputted or designated base data as the standard value, specified base data is set in a constant color prediction model. The outputting of the second color value corresponding to the first color value as the standard value from the color prediction model in which the specified base data was set can be performed for each individual base data. Determination can be performed regarding the base data whose color difference between the second color value outputted from the color prediction model and the second color value as the standard value is smallest. Further, in order to respond to changes in the characteristic features of the device over time, when there are cases where multiple base data correspond to the same device and are each created and stored at different periods, it becomes possible to search for base data with a high similarity (i.e., base data created when the characteristics were similar to those of the device) based on the creation period of each individual base data and the cycle of change in characteristics of the device. In this case as well, by generating color conversion conditions using base data to which the above-described complementary data was added, color conversion conditions that can perform even more suitable color conversion are obtainable.

Furthermore, in the fourth aspect of the present invention, when the color converting device is provided with a color conversion condition storage unit that stores a plurality of color conversion conditions generated in the past, acquisition of the complementary data with the acquisition unit can be performed by, for example, searching among color conversion conditions stored in the color conversion condition storage unit for color conversion conditions whose similarity with the color conversion conditions generated using the inputted or designated base data and color prediction model is high, reading out the color conversion conditions extracted by the search from the color conversion condition storage unit, and generating or acquiring the set of corresponding first color value and second color value from the read out color conversion conditions as the complementary data.

In the eighth aspect of the present invention, with regard to searching for color conversion conditions whose similarities are high with the color conversion conditions generated using the inputted or designated base data and color prediction model, an arbitrary first color value can be inputted to the color conversion conditions generated using, e.g., the inputted or designated base data and color prediction model and a second color value outputted through the color conversion by the color conversion conditions can be stored as the standard value. The arbitrary first color value can be inputted to each color conversion condition, and it can be determined which color conversion conditions have the smallest color difference between the second color value outputted via color conversion from the individual color conversion conditions and the second color value acting as the standard value. In this case as well, by generating color conversion conditions using base data to which the above-described complementary data was added, color conversion conditions that can perform even more suitable color conversion are obtainable.

Further, in any of the fourth through eighth aspects of the present invention, it is preferable that the device be further provided with, for example, a low-precision region detector that, in a case where it has been determined by the determining unit that the inputted or designated base data is not base data that can generate suitable color conversion conditions when combined with the inputted or designated color prediction model, the detector detects the precision of the base data as units of individual portion of color regions at the time the first or second color space is divided into a plurality portion of color regions, and detects low-precision portion of color regions where the precision of the data is lower than other portion of color regions. It is also preferable that the acquisition unit be configured to acquire complementary data corresponding to the low-precision portions of color regions detected by the low-precision region detector. Due to this, the acquisition and addition of complementary data to a low-precision portions of color regions where, from among the multiple portion of color regions, the data precision is lower than other portion of color regions is performed, and the base data precision, that is, the precision of the color conversion conditions can be efficiently improved.

Also, in the first embodiment of the present invention, there is a case where the color prediction model is an algorithm that sets a reference region of a predetermined size as the center of a specified position within the first or second color space, and estimates and calculates a relation between the specified position and the first color value and the second color value in the vicinity thereof based on color data in the reference region set in the data that forms the base data for each position in the first or second color space, thereby estimating and calculating the relation between the first color value and the second color value in the entire region in the first or second color space. The device can further be provided with a low-precision region detector that, in a case where it has been determined by the determining unit that the inputted or designated base data is not base data that can generate suitable color conversion conditions when combined with the inputted or designated color prediction model, detects the precision of the base data as units of individual portion of color regions at the time the first or second color space is divided into a plurality portion of color regions, and detects low-precision portion of color regions where the precision of the data is lower than other portion of color regions; and an enlarger that enlarges the size of the reference region applied when a relation between the first color value and the second color value in the low-precision portions of color regions and the vicinity thereof detected by the low-precision region detector is estimated and calculated using the color prediction model. Due to this, when the relations between the first color value and the second color value in the low-precision portions of color regions and the vicinity thereof is estimated and calculated using the color prediction model, this is performed based on a greater number of data. The precision of the color conversion conditions in the low-precision portions of color regions and the vicinity thereof can thus be made to improve.

In the first aspect of the present embodiment, it is preferable that the color converting device be further provided with a notifier that notifies at least the result of the determination in a case where it has been determined by the determining unit that the inputted or designated base data is not base data that can generate suitable color conversion conditions when combined with the inputted or designated color prediction model. Due to this, the user can at least confirm that color conversion conditions that can perform suitable color conversion cannot be obtained with the combination of the inputted or designated base data and color prediction model. For example, the same operations with the acquisition unit as explained earlier (operations like acquiring complementary data that complements the base data and adding it thereto) can be performed. The base data used in generating the color conversion conditions can be switched, if it is an environment where the base data can be switched. The color prediction model used in generating the color conversion conditions can be switched, if it is an environment where the color prediction model can be switched, and so on. Then, by reacting in this manner, suitable color conversion can be performed on the image data.

Note that in the eleventh aspect of the present invention, the color converting device can be further provided with a low-precision region detector that, in a case where it has been determined by the determining unit that the inputted or designated base data is not base data that can generate suitable color conversion conditions when combined with the inputted or designated color prediction model, detects the precision of the base data as units of individual portion of color regions when the first or second color space is divided into a plurality of portion of color regions and detects a low-precision portions of color regions where the precision of the data is lower than other portion of color regions, and the notifier also notifies of the low-precision portions of color regions detected by the low-precision region detector. In this case, the user who has recognized that color conversion conditions that can perform suitable color conversion with the combination of the inputted or designated base data and color prediction model cannot be obtained can recognize the necessity of adding complementary data corresponding to a portion of color region to the base data upon acquiring complementary data that complements the base data and adding it thereto. Accordingly, it is easy to perform an operation where complementary data that corresponds to the low-precision portions of color regions can be obtained and added to the base data.

Also, in the eleventh aspect of the present invention, the color converting device can be configured so that, in a case where it has been determined by the determining unit that the inputted or designated base data is not base data that can generate suitable color conversion conditions when combined with the inputted or designated color prediction model, the notifier performs sending processing that sends request data requesting the submission of new base data or question data that asks how to deal with the determination results to a sending destination registered in advance (e.g., the manufacturer, a group that the user belongs to or participates in, like another person in the industry, in an organization, or an online community). Due to this, when it has been determined by the determining unit that the inputted or designated base data is not base data that can generate suitable color conversion conditions when combined with the inputted or designated color prediction model, the above-described request data or question data is automatically sent by the notifier. The user can receive base data submissions from the manufacturer or another party based on the request data, and answers (solutions) based on the question data, whereby the user can easily handle the problem so as to be able to perform suitable color conversion on the image data.

Note that in any of the ninth, tenth and twelfth aspects of the present invention, detection of 14, the low-precision region detector detects in every individual portion of color region the number of data that corresponds to the individual portion of color regions, included in the base data as the precision of the base data that designates each individual portion of color region as a unit, and detects a portion of color region as the low-precision portions of color regions whose number of corresponding data is less than other portion of color regions, or generates color conversion conditions for evaluation using data from which a predetermined ratio of data corresponding to a specified portion of color region has been removed and the inputted or designated color prediction model from the multiple portion of color regions in the base data, and for the second color value obtained from the evaluation color conversion conditions, the color difference between a second color value obtained from color conversion conditions generated using the inputted or designated base data and color prediction model or a second color value showing the data removed from the base data is sought and performed for each portion of color region, whereby the color differences for each portion of color region is sought as the base data for the individual portion of color regions, and the portion of color region where the color difference is larger than other portion of color regions is detected as the low-precision portions of color regions.

The color conversion method according to the fifteenth aspect of the present invention includes: inputting or designating base data that regulates a plurality of color charts for a first color value on a first color space and a second color value on a second color space that represent colors on a specified color chart, and a color prediction model that estimates and calculates the relation of the first color value and second color value based on the base data; generating color conversion conditions using the inputted or designated base data and color prediction model to convert the first color value into the second color value; and converting inputted image data based on the generated color conversion conditions, upon which it is determined by calculation processing whether the inputted or designated base data is base data that can generate suitable color conversion conditions when combined with the inputted or designated color prediction model. Accordingly, as in the first aspect of the present invention, the suitability of the combination of the base data and color prediction model used in generating the color conversion conditions can be confirmed in advance.

In the color conversion program-storing medium according to the sixteenth aspect of the present invention, the program makes a computer, that functions as a color conversion device that: inputs or designates base data that regulates a plurality of color charts for a first color value on a first color space and a second color value on a second color space that represent colors on a specified color chart, and a color prediction model that estimates and calculates the relation of the first color value and second color value based on the base data; generates color conversion conditions for converting the first color value into the second color value using the inputted or designated base data and color prediction model; and performs color conversion of inputted image data based on the generated color conversion conditions; also function as a determining unit that determines whether the inputted or designated base data is base data that can generate suitable color conversion conditions when the inputted or designated color prediction model is combined therewith.

The color conversion program-storing medium according to the sixteenth aspect of the present invention makes the computer function as the above-described color converting device and stores a program for making it function as the above-described determining unit. So the computer executes the color conversion program stored in the program-storing medium according to the sixteenth aspect of the present invention, whereby the computer comes to function as the color converting device of the first aspect of the present invention. As in the first aspect, the suitability of the combination of the base data and color prediction model used in generating the color conversion conditions can be confirmed in advance.

As explained above, the present invention is a color converting device. The base data regulates multiple color chart regarding a first color value on a first color space and a second color value on a second color space that represent colors of a specified color chart and a color prediction model estimates and calculates the relation between the first color value and the second color value based on the base data, and the base data and color prediction model are inputted or designated. The inputted or designated base data and color prediction model are used and color conversion conditions for converting the first color value to the second color value are generated, and the device performs color conversion of inputted image data based on the generated color conversion conditions. The device is configured so as to determine with calculation processing whether the inputted or designated base data is base data that can generate suitable color conversion conditions when the base data is combined with the inputted or designated color prediction model. The device thus exhibits an excellent effect in being able to confirm in advance the suitability of the combination of the inputted or designated base data and color prediction model used in generating the color conversion conditions.

What is claimed is:

1. A color converting device, wherein base data regulates a plurality of color charts regarding a first color value on a first color space and a second color value on a second color space that represent colors of a specified color chart and a color prediction model that estimates and calculates the relation between the first color value and the second color value based on the base data are inputted or designated, and the inputted or designated base data and color prediction model are used and color conversion conditions for converting the first color value to the second color value are generated, the device performing color conversion of inputted image data based on the generated color conversion conditions and provided with
a determining unit that determines with calculation processing whether the inputted or designated base data is base data that can generate suitable color conversion conditions when the base data is combined with the inputted or designated color prediction model.

2. The color converting device of claim 1, wherein the base data generates a specified color chart based on one of the first color value and second color value that represent a color of a specified color chart, and measures the color of the other one of the first color value and second color value of the generated specified color chart, for a plurality of color charts.

3. The color converting device of claim 1, wherein the determining unit performs determination with calculation processing as to whether the inputted or designated base data is base data that can generate the suitable color conversion conditions when combined with the inputted or designated color prediction model, by generating color conversion conditions for evaluation using data, which is obtained by excluding predetermined ratio data from the inputted or designated base data, and the inputted or designated color prediction model, and with regard to the second color value obtained from the color conversion conditions for evaluation, determining whether a color difference of the second color value obtained from the generated color conversion conditions using the inputted or designated base data and color prediction model or a second color value representing the data removed from the base data is below a threshold.

4. The color converting device of claim 1, further provided with an acquisition unit that acquires complementary data that complements the base data and adds the acquired complementary data to the base data when it has been determined by the determining unit, when the inputted or designated base data is combined with the inputted or designated color prediction model, that the base data is not base data that can generate the suitable color conversion conditions.

5. The color converting device of claim 4, wherein the acquisition unit generates or acquires a corresponding set of the first color value and the second color value as the complementary data from the color conversion conditions generated using the inputted or designated base data and color prediction model.

6. The color converting device of claim 4, further provided with a color prediction model storage unit that stores a plurality of color prediction models, wherein the acquisition unit reads out a color prediction model that differs from the inputted or designated color prediction model from the plurality of color prediction models stored in the color prediction model storage unit and uses the color prediction model read out from the color prediction model storage unit and the inputted or designated base data and generates color conversion conditions for generating complementary data, and generates or acquires the set of the corresponding first color value and second color value as the complementary data from the generated color conversion conditions for generating complementary data.

7. The color converting device of claim 4, further provided with a base data storage unit that stores a plurality of base data inputted in the past,
wherein the acquisition unit searches among base data stored in the base data storage unit for base data whose similarity with the inputted or designated base data is high, reads out base data extracted by the search from the base data storage unit, and acquires the set of corresponding first color value and second color value from the read out base data as the complementary data.

8. The color converting device of claim 4, further provided with a color conversion condition storage unit that stores a plurality of color conversion conditions generated in the past,
wherein the acquisition unit searches among color conversion conditions stored in the color conversion condition storage unit for color conversion conditions whose similarity with the color conversion conditions generated using the inputted or designated base data and color prediction model is high, reads out the color conversion conditions extracted by the search from the color conversion condition storage unit, and generates or acquires the set of corresponding first color value and second color value from the read out color conversion conditions as the complementary data.

9. The color converting device of claim 4, further provided with a low-precision region detector that, in a case where it has been determined by the determining unit that the inputted or designated base data is not base data that can generate suitable color conversion conditions when combined with the inputted or designated color prediction model, detects the precision of the base data as units of individual portion of color regions at the time the first or second color space is divided into a plurality portion of color regions, and detects low-precision portion of color regions where the precision of the data is lower than other portion of color regions, and the acquisition unit acquires complementary data corresponding to the low-precision portions of color regions detected by the low-precision region detector.

10. The color converting device of claim 1, wherein the color prediction model is an algorithm that sets a reference region of a predetermined size as the center of a specified position within the first or second color space estimates and calculates a relation between the specified position and the first color value and the second color value in the vicinity thereof based on color data in the reference region set in the data that forms the base data for each position in the first or second color space, thereby estimating and calculating the relation between the first color value and the second color value in the entire region in the first or second color space, the device further provided with
a low-precision region detector that, in a case where it has been determined by the determining unit that the inputted or designated base data is not base data that can generate suitable color conversion conditions when combined with the inputted or designated color prediction model, detects the precision of the base data as units of individual portions of color regions at the time the first or second color space is divided into a plurality of portions of color regions, and detects a low-precision portion of color regions where the precision of the data is lower than other portions of color regions; and
an enlarger that enlarges the size of the reference region applied when a relation between the first color value and the second color value in the low-precision portions of color regions and the vicinity thereof detected by the low-precision region detector is estimated and calculated using the color prediction model.

11. The color converting device of claim 1, further provided with a notifier that notifies at least the result of the determination in a case where it has been determined by the determining unit that the inputted or designated base data is not base data that can generate suitable color conversion conditions when combined with the inputted or designated color prediction model.

12. The color converting device of claim 11, further provided with a low-precision region detector that, in a case where it has been determined by the determining unit that the inputted or designated base data is not base data that can generate suitable color conversion conditions when combined with the inputted or designated color prediction model, detects the precision of the base data as units of individual portion of color regions when the first or second color space is divided into a plurality of portion of color regions and detects a low-precision portions of color regions where the precision of the data is lower than other portion of color regions, and the notifier also notifies of the low-precision portions of color regions detected by the low-precision region detector.

13. The color converting device of claim 11, wherein, in a case where it has been determined by the determining unit that the inputted or designated base data is not base data that can generate suitable color conversion conditions when combined with the inputted or designated color prediction model, the notifier performs sending processing that sends request data requesting the submission of new base data or question data that asks how to deal with the determination results to a sending destination registered in advance.

14. The color converting device of claim 9, wherein the low-precision region detector detects in every individual portion of color region the number of data that corresponds to the individual portion of color regions, included in the base data as the precision of the base data that designates each individual portion of color region as a unit, and detects a portion of color region as the low-precision portions of color regions whose number of corresponding data is less than other portion of color regions, or generates color conversion conditions for evaluation using data from which a predetermined ratio of data corresponding to a specified portion of color region has been removed and the inputted or designated color prediction model from the multiple portion of color regions in the base data, and for the second color value obtained from the evaluation color conversion conditions, the color difference between a second color value obtained from color conversion conditions generated using the inputted or designated base data and color prediction model or a second color value showing the data removed from the base data is sought and performed for each portion of color region, whereby the color differences for each portion of color region is sought as the base data for the individual portion of color regions, and the portion of color region where the color difference is larger than other portion of color regions is detected as the low-precision portions of color regions.

15. A color conversion method comprising:
inputting or designating base data that regulates a plurality of color charts for a first color value on a first color space and a second color value on a second color space that represent colors on a specified color chart, and a color prediction model that estimates and calculates the relation of the first color value and second color value based on the base data;
generating color conversion conditions using the inputted or designated base data and color prediction model to convert the first color value into the second color value; and
converting inputted image data based on the generated color conversion conditions, upon which it is determined by calculation processing whether the inputted or designated base data is base data that can generate suitable color conversion conditions when combined with the inputted or designated color prediction model.

16. A tangible medium storing a color conversion program that makes a computer, that functions as a color conversion device that:
inputs or designates base data that regulates a plurality of color charts for a first color value on a first color space and a second color value on a second color space that represent colors on a specified color chart, and a color prediction model that estimates and calculates the relation of the first color value and second color value based on the base data;
generates color conversion conditions for converting the first color value into the second color value using the inputted or designated base data and color prediction model; and
performs color conversion of inputted image data based on the generated color conversion conditions; also function as a determining unit that determines whether the inputted or designated base data is base data that can generate suitable color conversion conditions when the inputted or designated color prediction model is combined therewith.
